(19) United States
(12) Patent Application Publication
(10) Pub. No.: US 2026/0031147 A1
(43) Pub. Date: Jan. 29, 2026

(54) Methods Used In Forming Memory Circuitry

(71) Applicant: Micron Technology, Inc., Boise, ID (US)

(72) Inventors: Darwin A. Clampitt, Wilder, ID (US); Arun Kumar Dhayalan, Boise, ID (US); Collin Howder, Boise, ID (US)

(73) Assignee: Micron Technology, Inc., Boise, ID (US)

(21) Appl. No.: 19/231,975

(22) Filed: Jun. 9, 2025

Related U.S. Application Data
(60) Provisional application No. 63/676,055, filed on Jul. 26, 2024.

(51) Int. Cl. G11C 16/04; G11C 5/06; H10B 41/27; H10B 41/35; H10B 43/27; H10B 43/35; H10D 30/01; H10D 30/68; H10D 30/69; H10D 62/83; H10D 64/01

(52) U.S. Cl. CPC G11C 16/0483; G11C 5/063; H10B 41/27; H10B 41/35; H10B 43/27; H10B 43/35; H10D 30/0411; H10D 30/0413; H10D 30/689; H10D 30/693; H10D 62/83; H10D 64/037

(57) ABSTRACT

A method used in forming memory circuitry comprising strings of memory cells comprising channel-material strings comprises forming a stack comprising vertically-alternating first tiers and second tiers. The first tiers are conductive and the second tiers are insulative at least in a finished-circuitry construction. A first set of horizontally-spaced pairs of channel-material strings are formed to extend through the first tiers and the second tiers. After forming the first set, a second set of horizontally-spaced pairs of channel-material strings is formed to extend through the first tiers and the second tiers. The pairs in the first set individually horizontally alternating with the pairs in the second set. Other embodiments, including structure, are disclosed.

### TECHNICAL FIELD

Embodiments disclosed herein pertain to memory arrays comprising strings of memory cells and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIG. 1-4 are diagrammatic sectional views of a portion of memory circuitry in process in accordance with embodiments of the invention.

FIGS. 5-91 are diagrammatic sectional, expanded, enlarged, and/or partial views of the construction of FIGS. 1-4 and/or of alternate embodiments.

### DETAILED DESCRIPTION OF EXAMPLE EMBODIMENTS

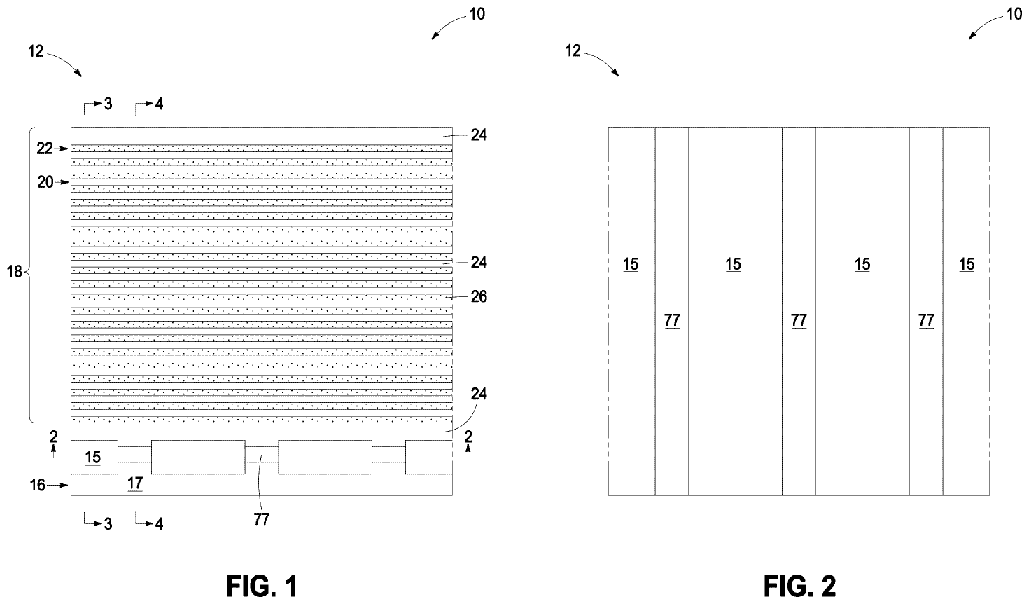

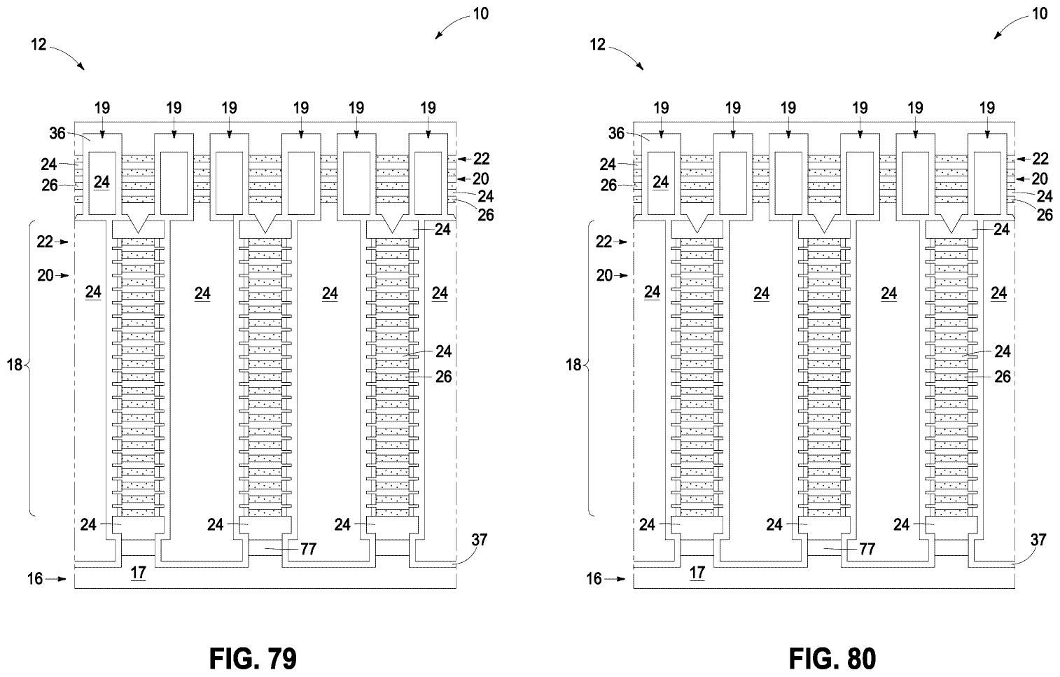

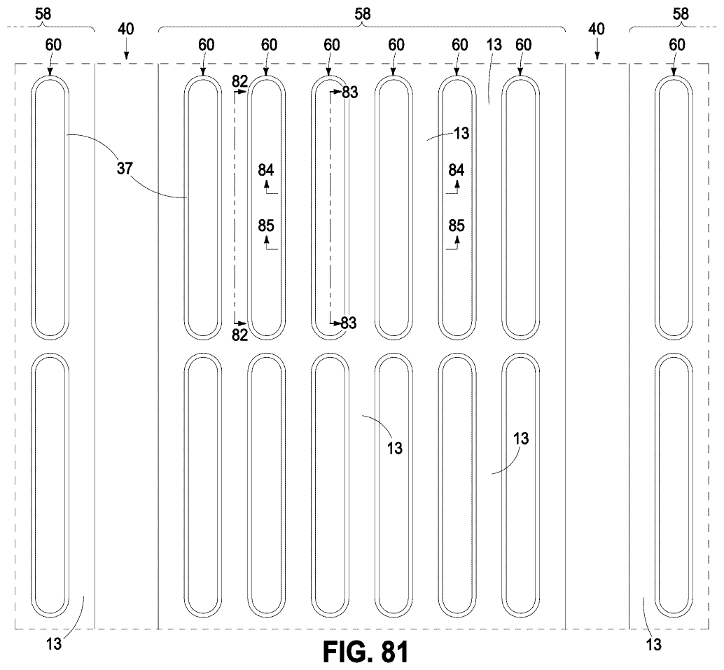

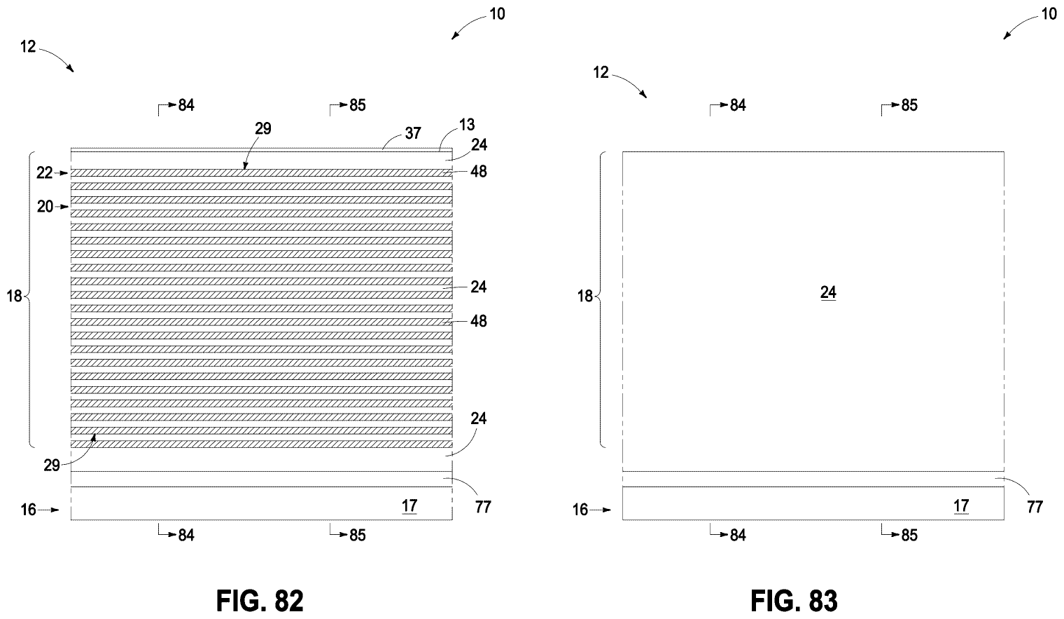

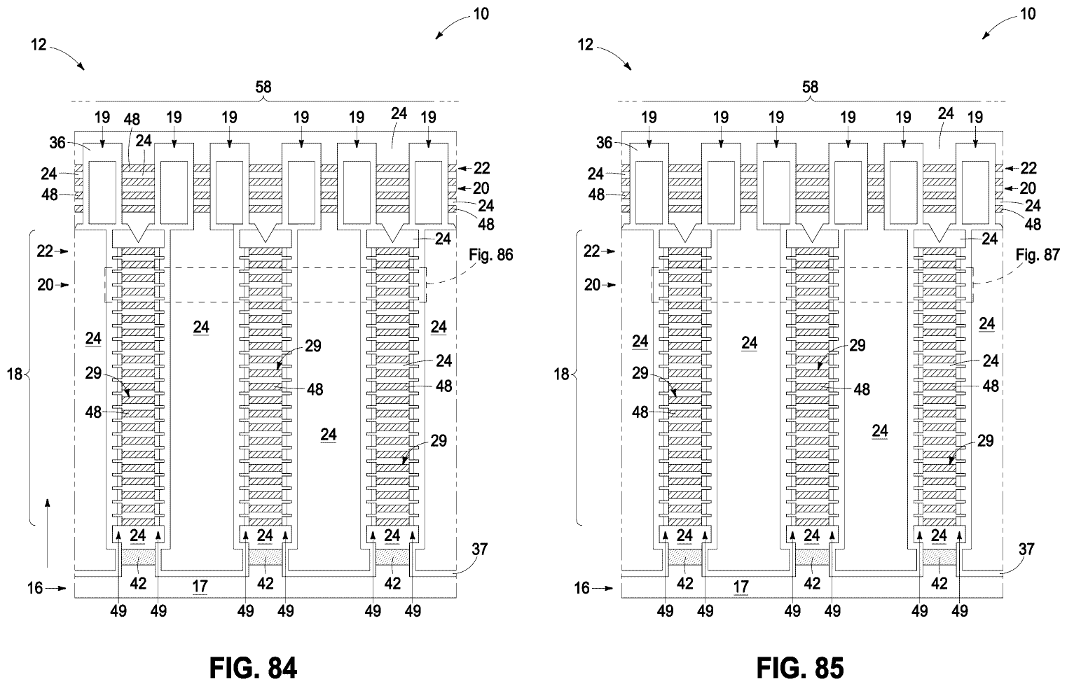

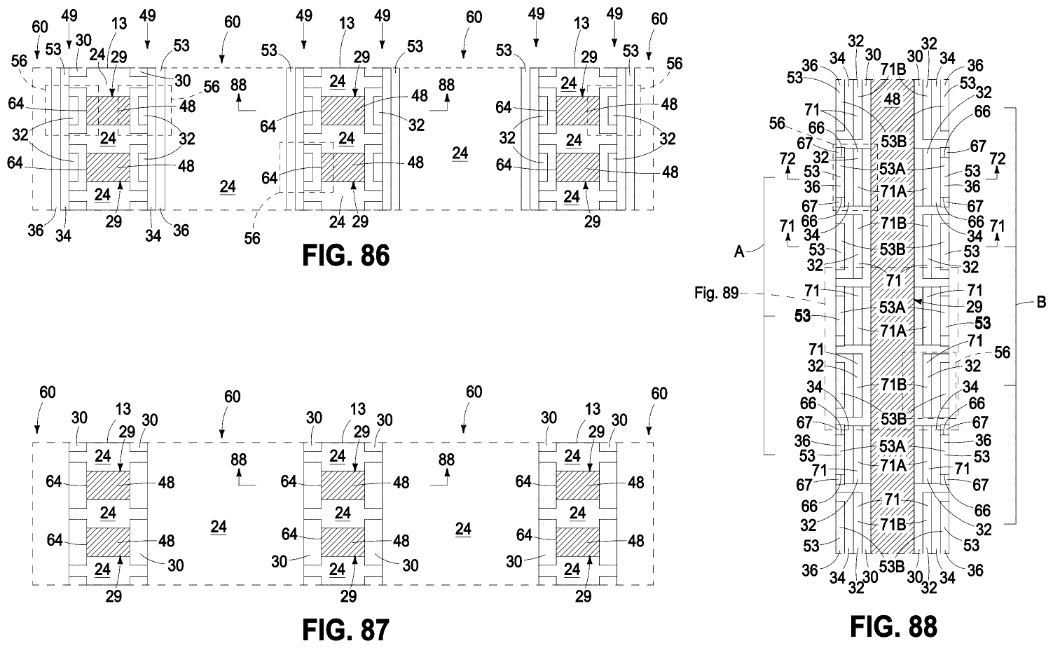

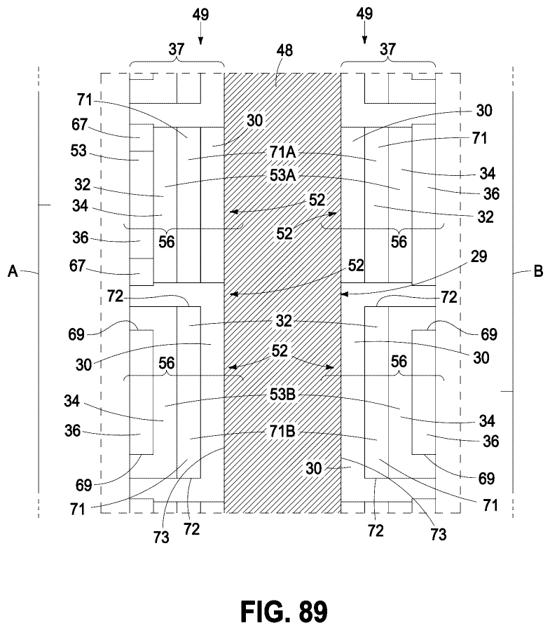

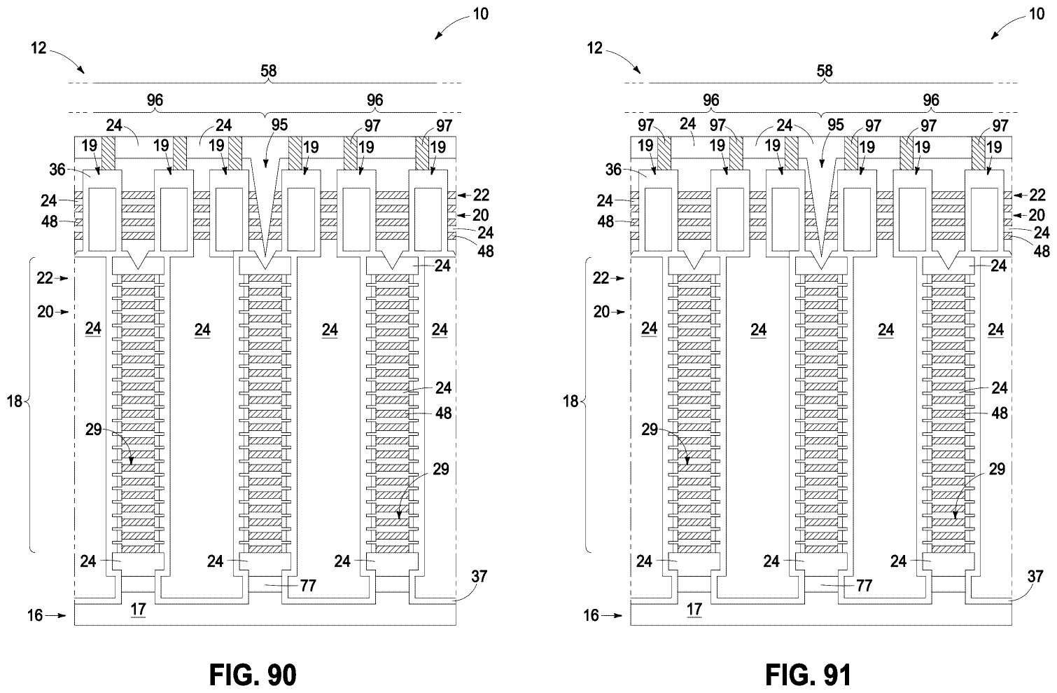

Embodiments of the invention encompass methods used in forming integrated circuitry, for example memory circuitry comprising a memory array, for example an array of NAND or other memory cells (e.g., integrated-circuitry components) that may have at least some peripheral control circuitry under the array (e.g., CMOS-under-array). Alternately, and by way of examples only, peripheral control circuitry may be above the array or to a side of the array. Embodiments of the invention encompass “gate-last” or “replacement-gate” processing, so-called “gate-first” processing, and other processing whether existing or future-developed independent of when transistor gates are formed. Embodiments of the invention also encompass integrated circuitry such as that comprising a memory array comprising strings of memory cells (e.g., NAND architecture) independent of method of manufacture. Some example embodiments are described with reference to FIGS. 1-91.

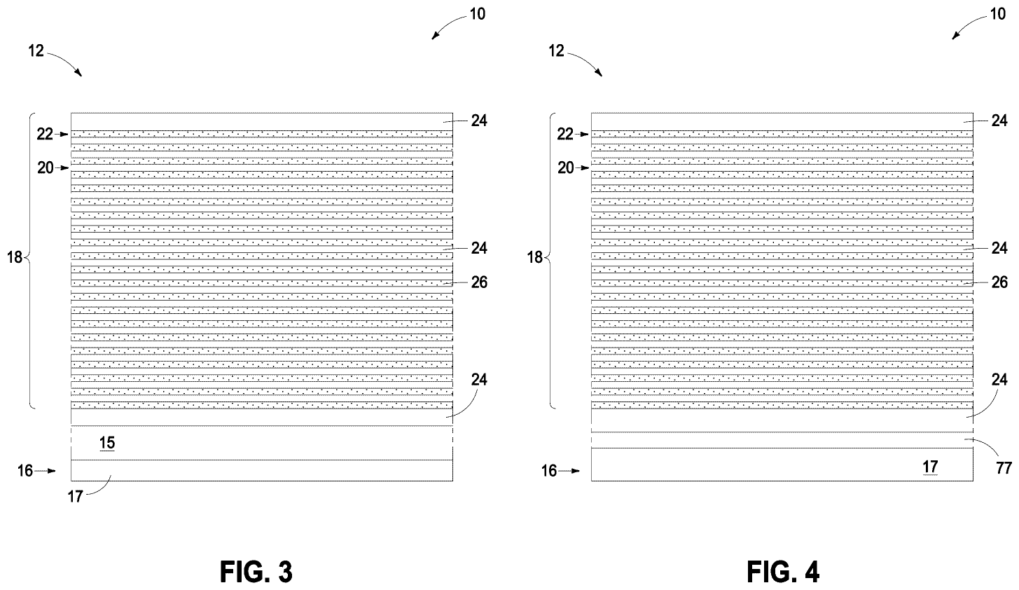

FIGS. 1-4 show an example construction 10 with an array 12 in which strings of memory cells will be formed. Example construction 10 may include a lowest base substrate (not shown) having any one or more of conductive/conductor/conducting, semiconductive/semiconductor/semiconducting, or insulative/insulator/insulating (i.e., electrically herein) materials. Various materials may be formed above the base substrate. Materials may be aside, elevationally inward, or elevationally outward of the FIGS. 1-4 depicted materials. For example, other partially or wholly fabricated components of integrated circuitry may be provided somewhere above, about, or within a base substrate. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

Construction 10 comprises a conductor tier 16 comprising conductor material 17 (e.g., WSiₓ under conductively-doped polysilicon). Conductor tier 16 may comprise part of control circuitry (e.g., peripheral-under-array circuitry and/or a common source line or plate) used to control read and write access to the transistors and/or memory cells in array 12. A stack 18 comprising vertically-alternating first/conductive tiers 22 and second/insulative tiers 20 has been formed above conductor tier 16. Example thickness for each of tiers 20 and 22 is 20 to 60 nanometers. The example uppermost tier 20 may be thicker/thickest compared to one or more other tiers 20 and/or 22. Only a small number of tiers 20 and 22 is shown, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22 and/or above an uppermost of the conductive tiers 22. For example, one or more select-gate tiers (not shown) may be between conductor tier 16 and the lowest conductive tier 22. Conductive tiers 22 may not be conductive at this point of processing, for example if “gate-last”/“replacement gate”, and insulative tiers 20 may not be insulative at this point of processing (but will be at least in a finished-circuitry construction). Regardless, in some embodiments conductive tiers 22 are referred to as first tiers 22 and insulative tiers 20 are referred to as second tiers 20, and which are of different compositions relative one another. Example insulative/second tiers 20 comprise insulative material 24 (e.g., silicon dioxide and/or other material that may be of one or more composition(s)). Example conductive/first tiers 22 comprise sacrificial material 26 (e.g., silicon nitride) in the example gate-last processing. Such would comprise conductive material (not shown) in so-called gate-first processing.

In one embodiment, between conductor tier 16 and stack 18 is a tier comprising sacrificial etch-stop material 15 (e.g., metal material) and sacrificial material 77 (e.g., polysilicon), the latter of which may be removed later and substituted with conductive material if forming lateral connection to sidewalls of channel material for directly electrically coupling such to conductor material 17 of conductor tier 16.

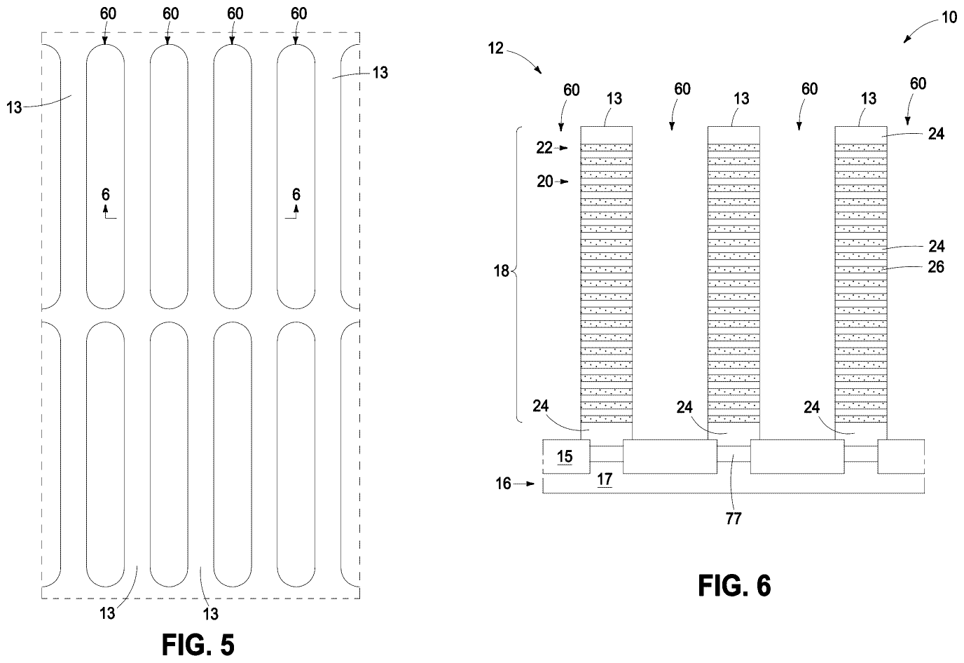

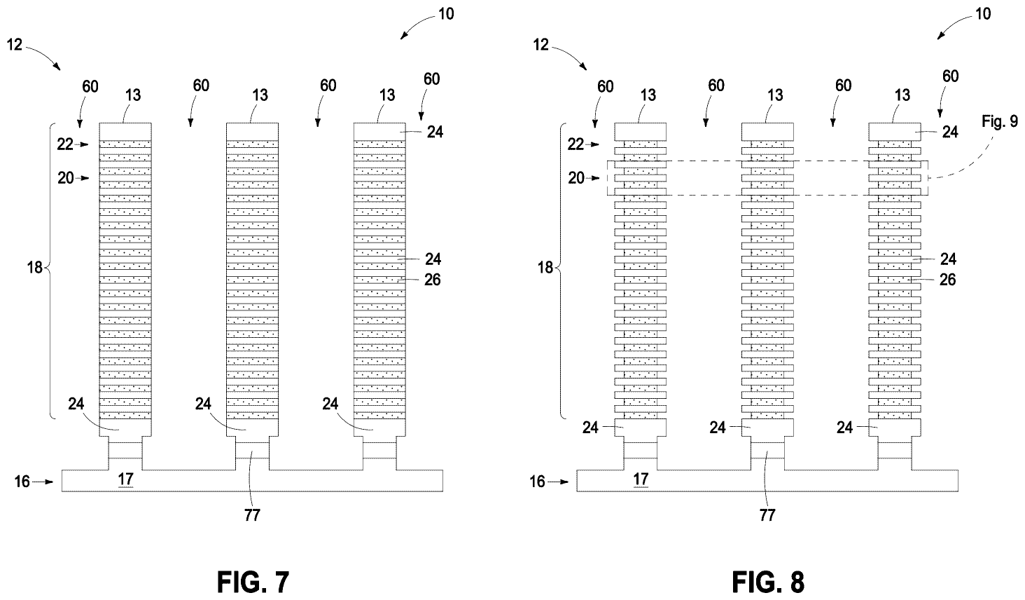

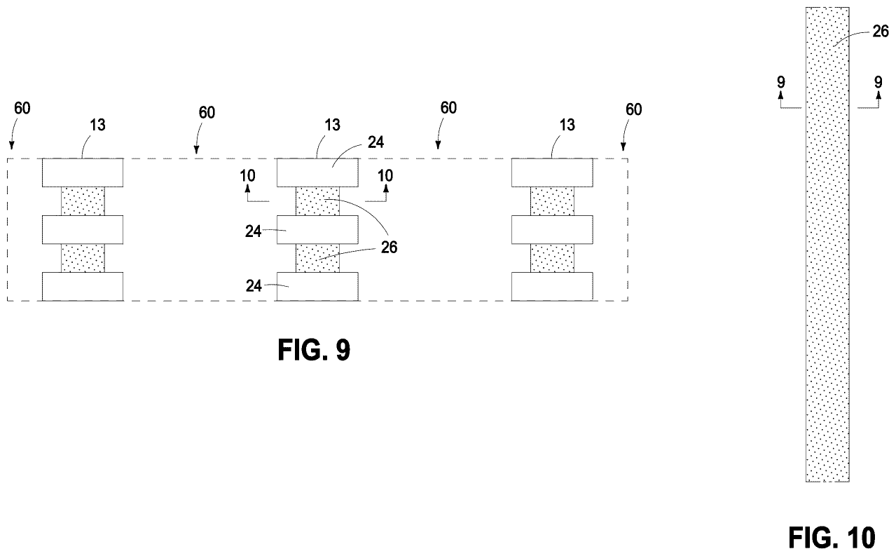

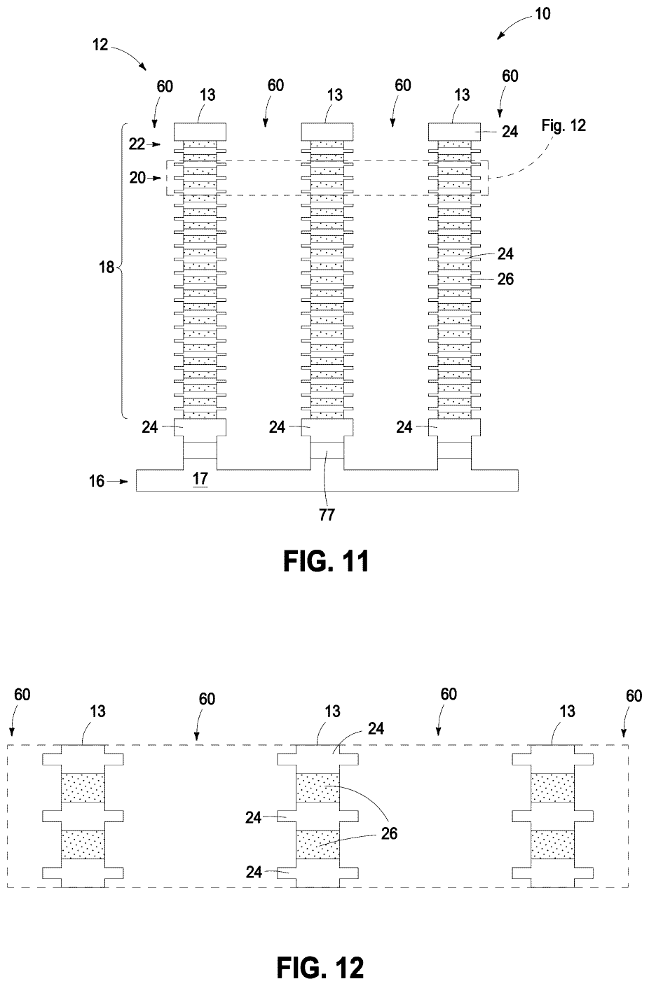

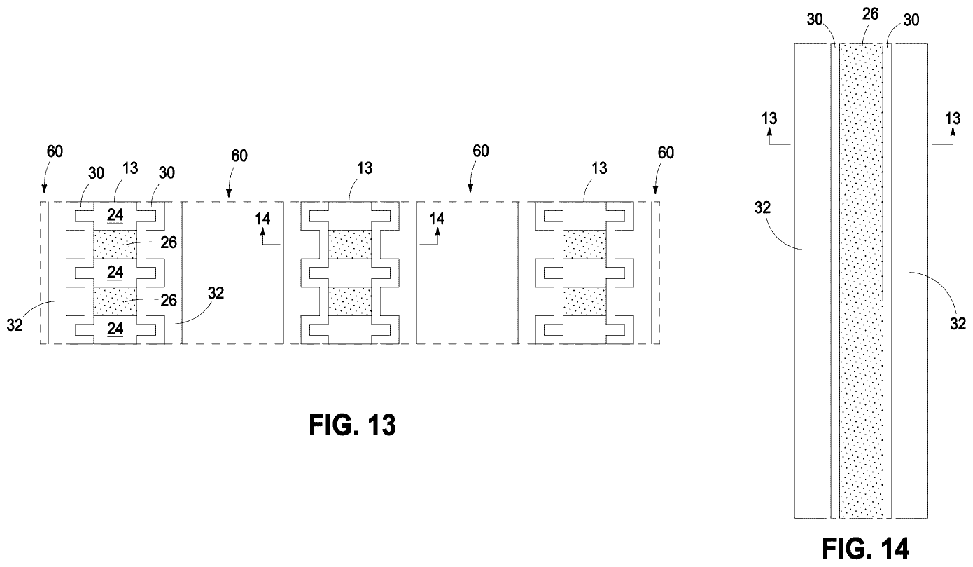

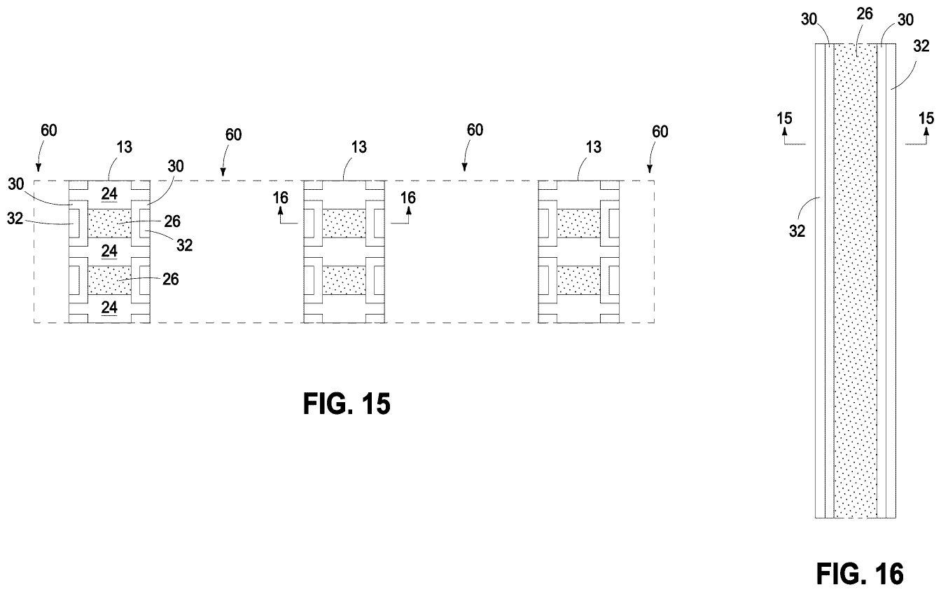

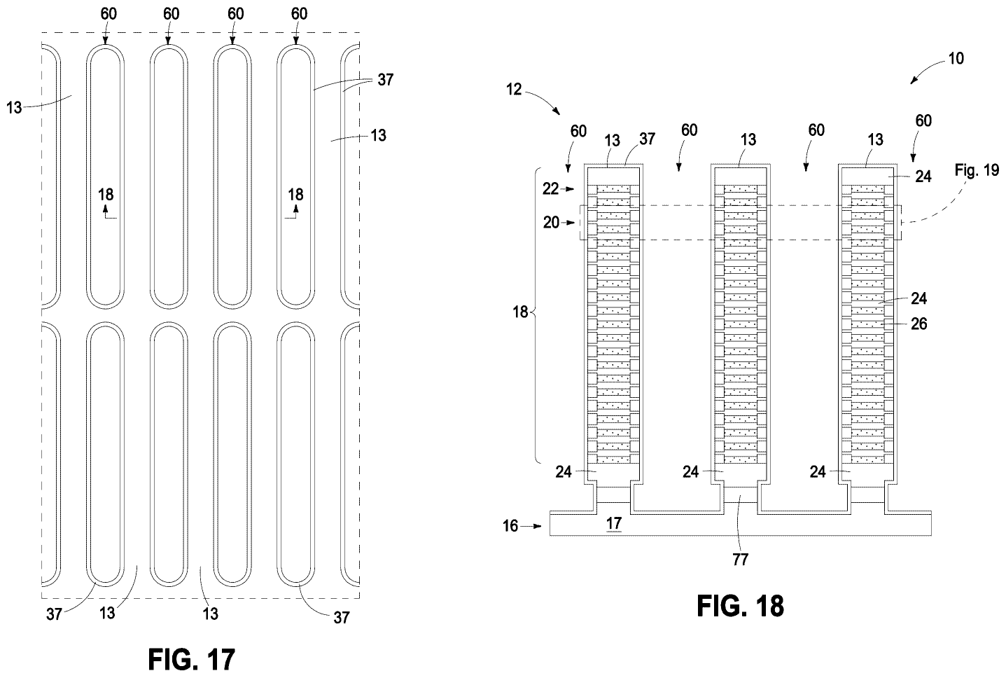

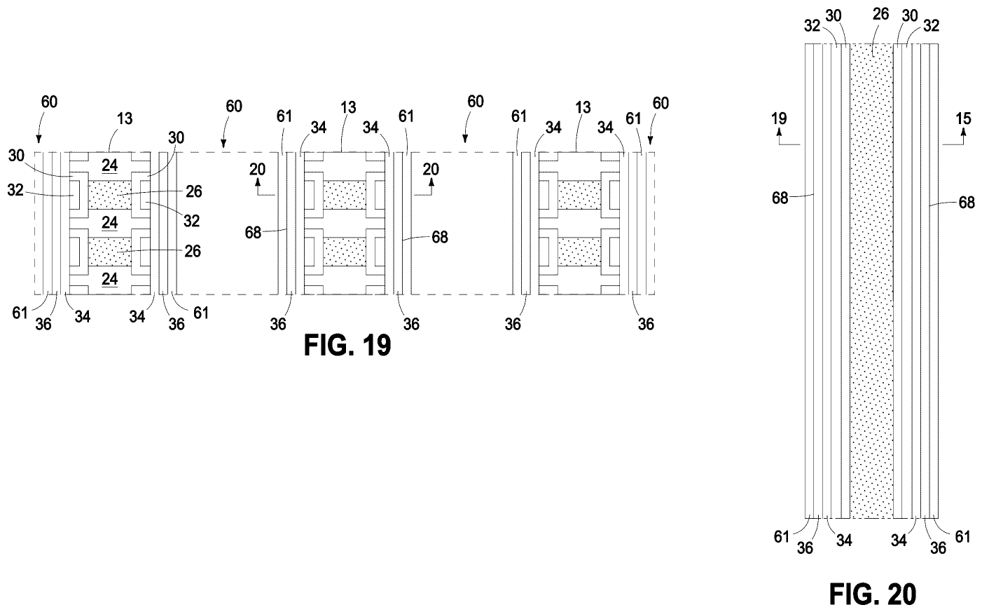

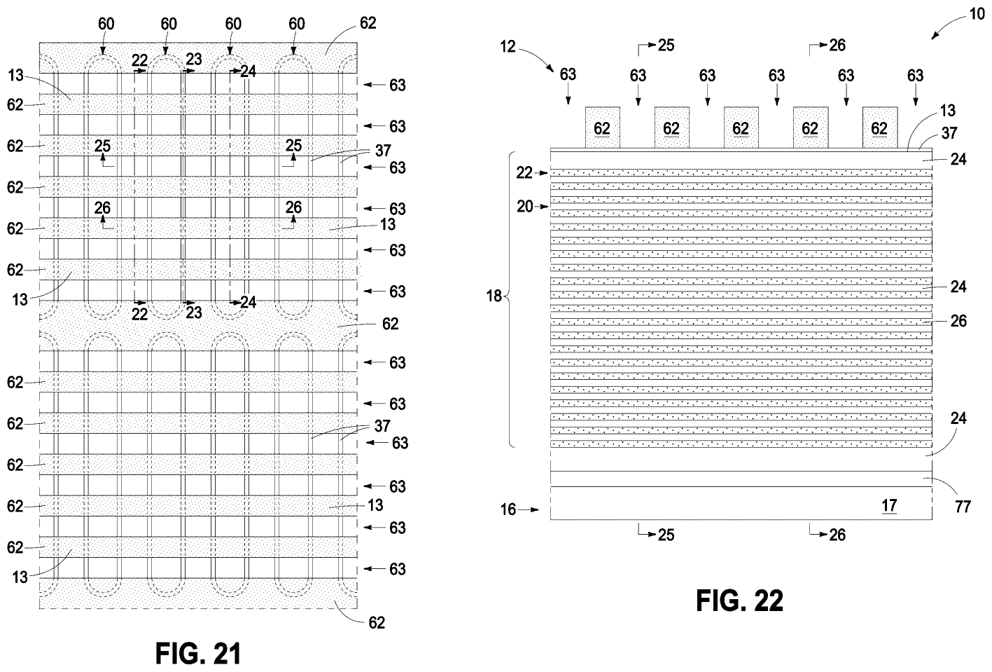

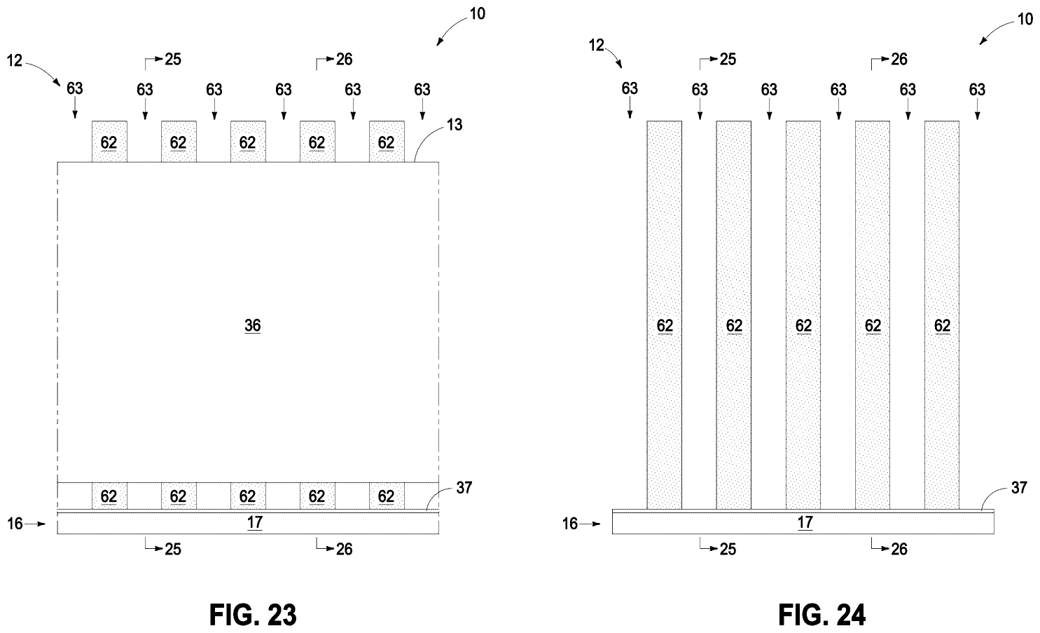

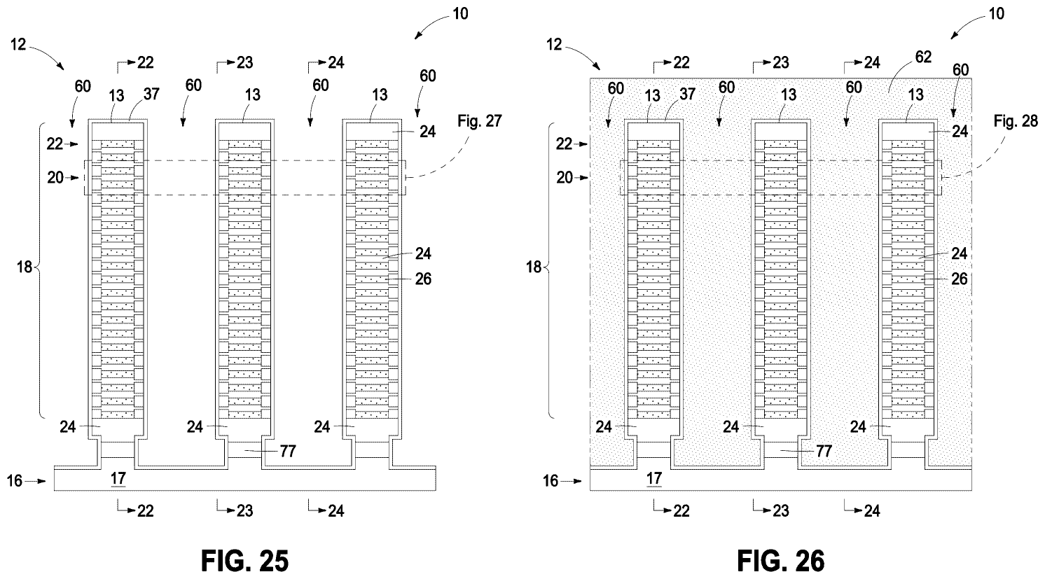

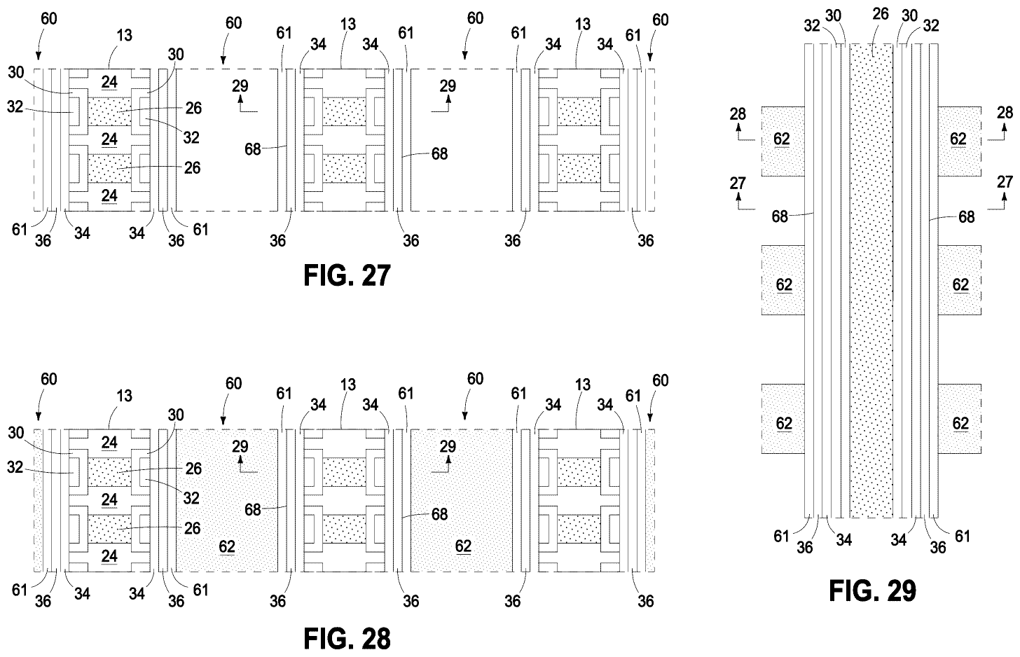

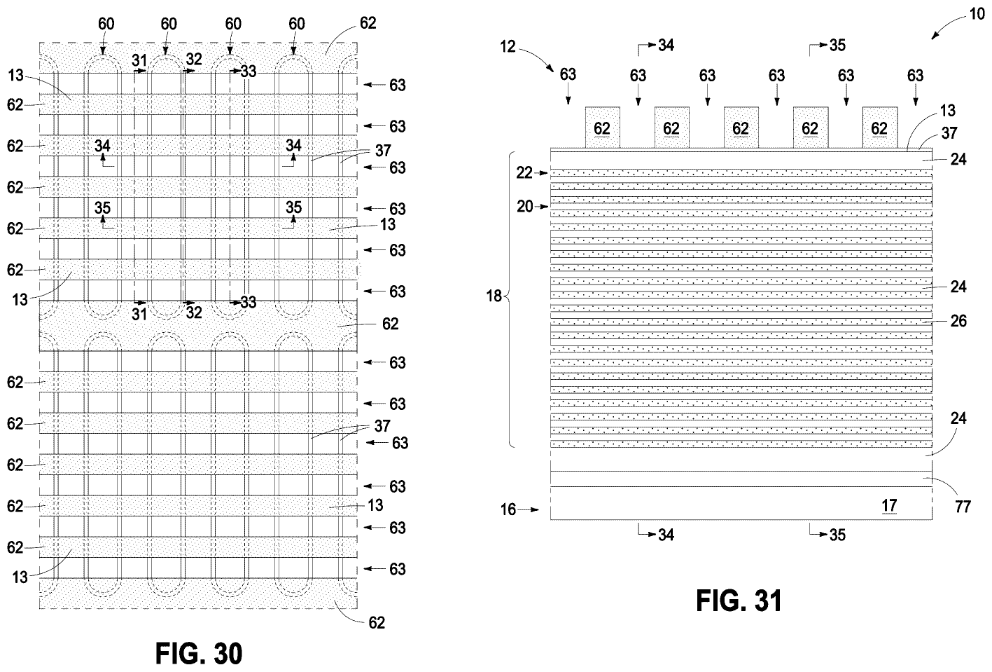

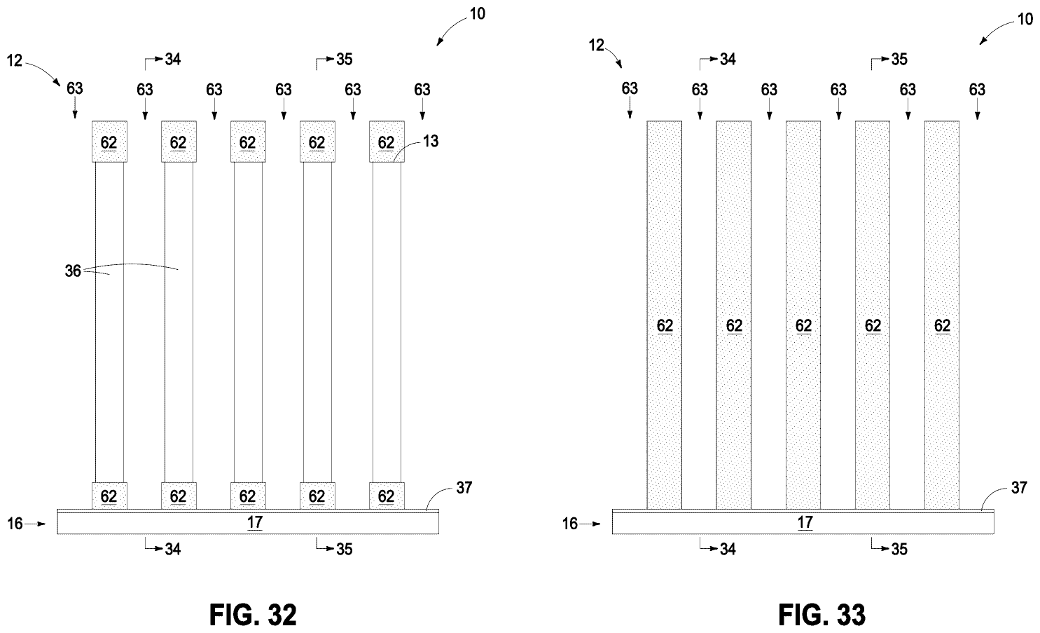

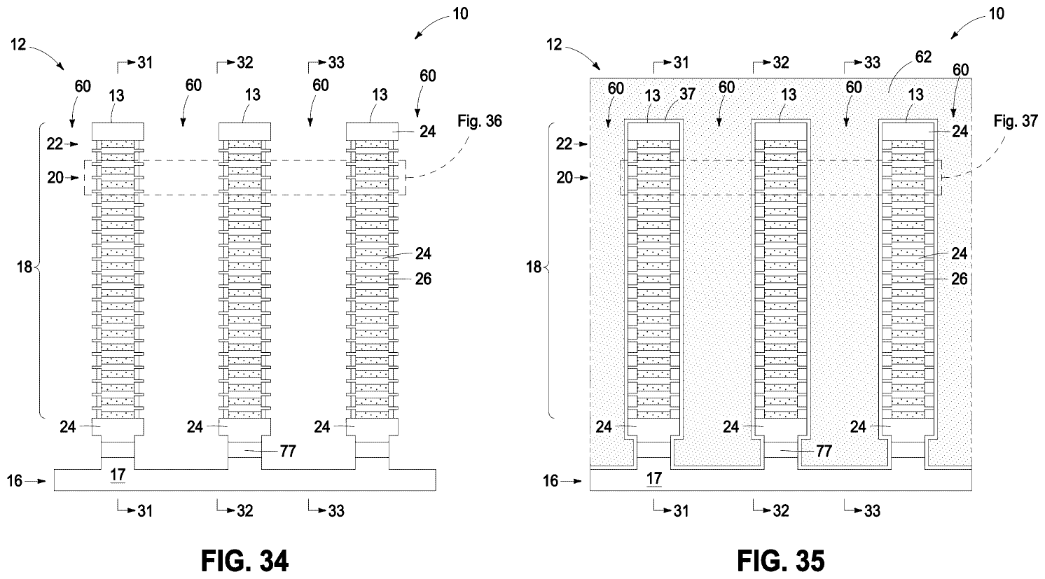

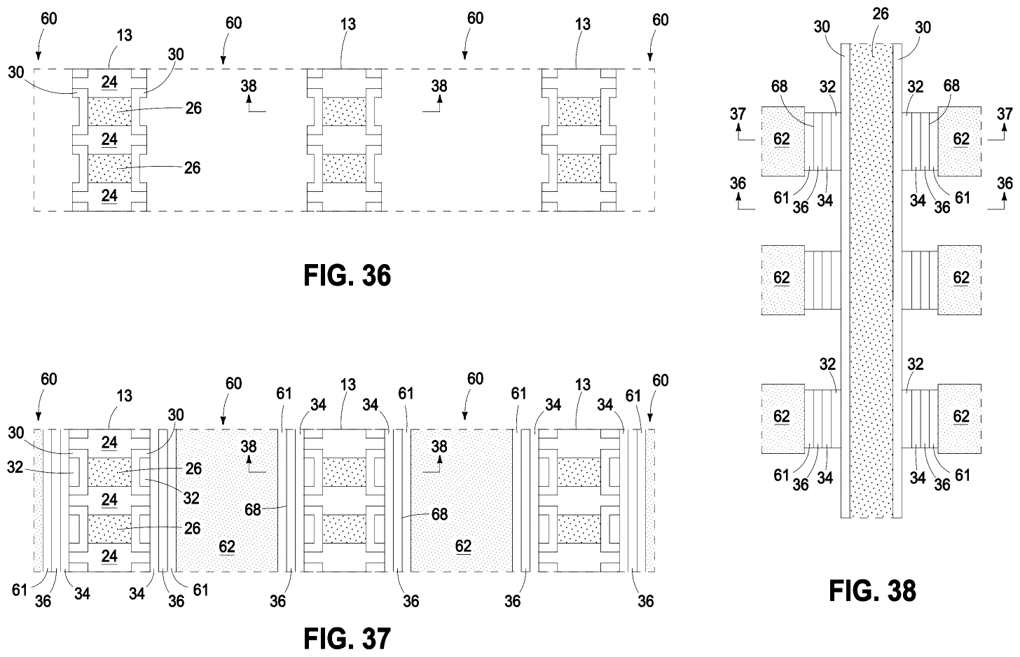

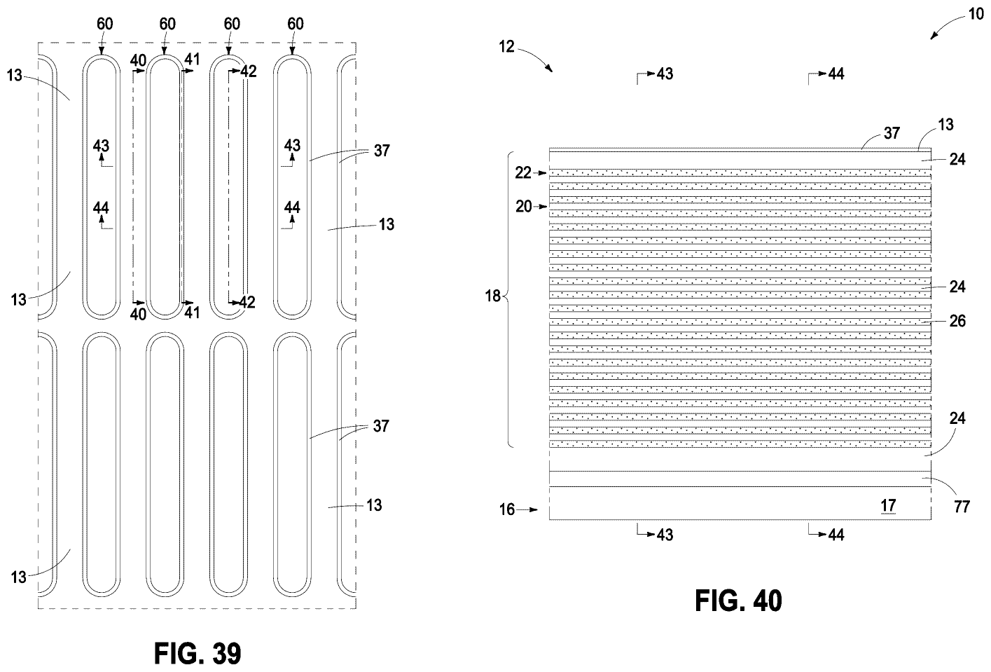

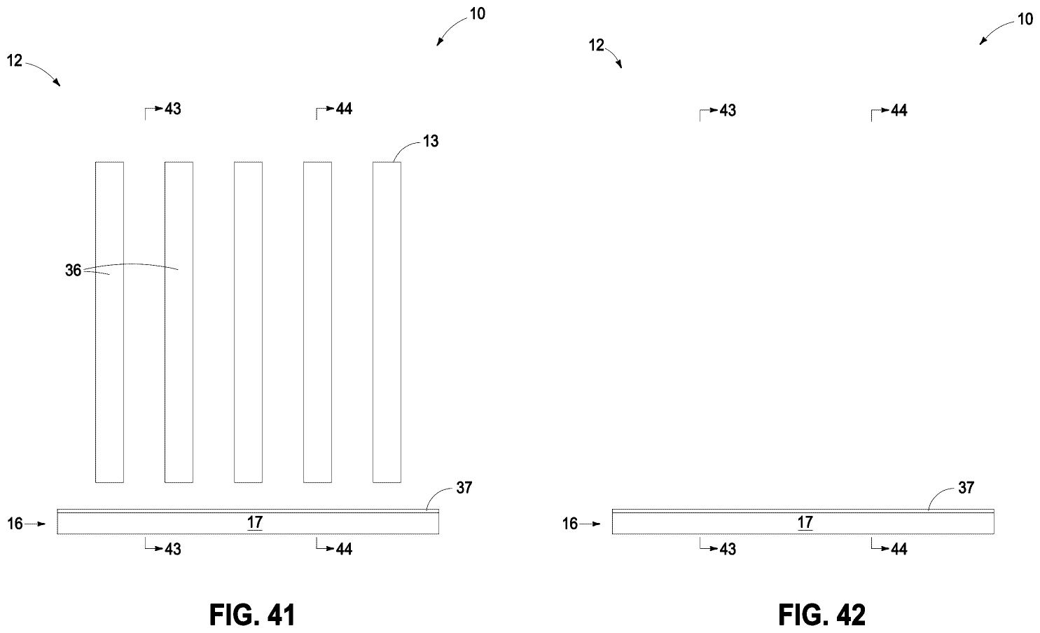

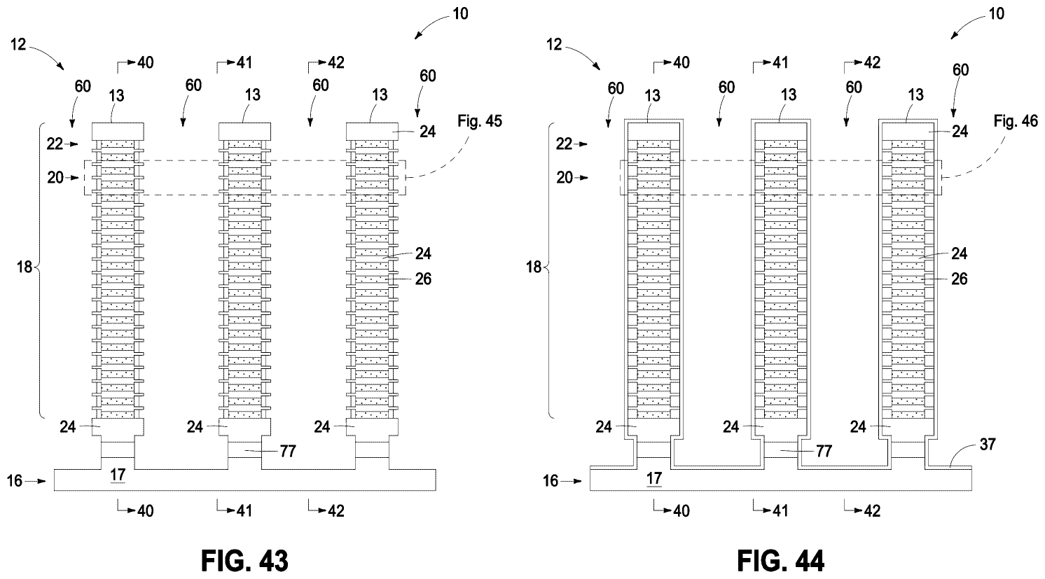

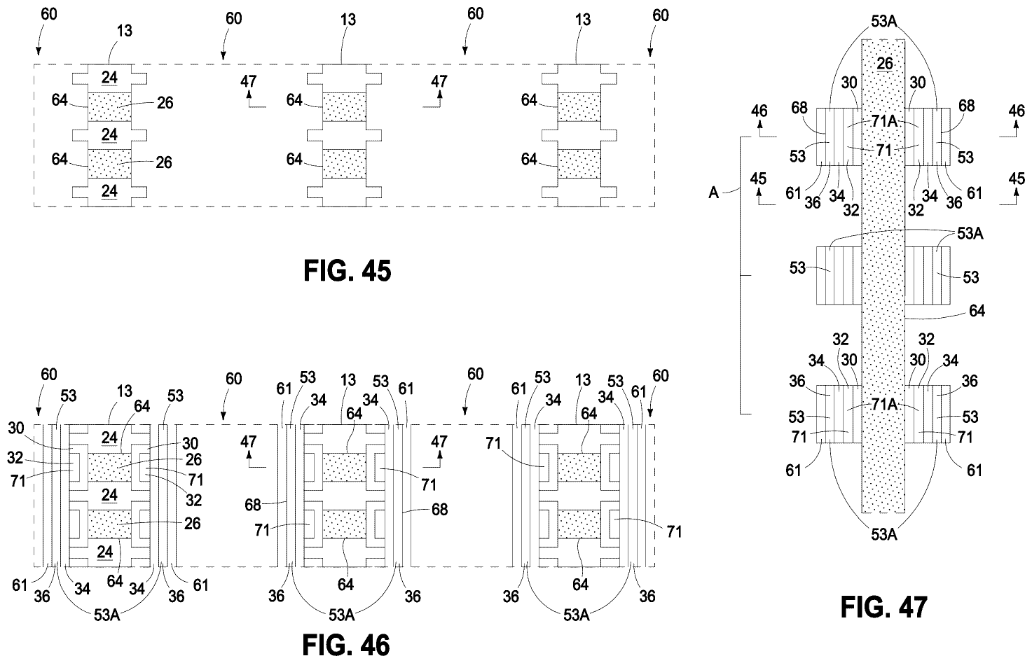

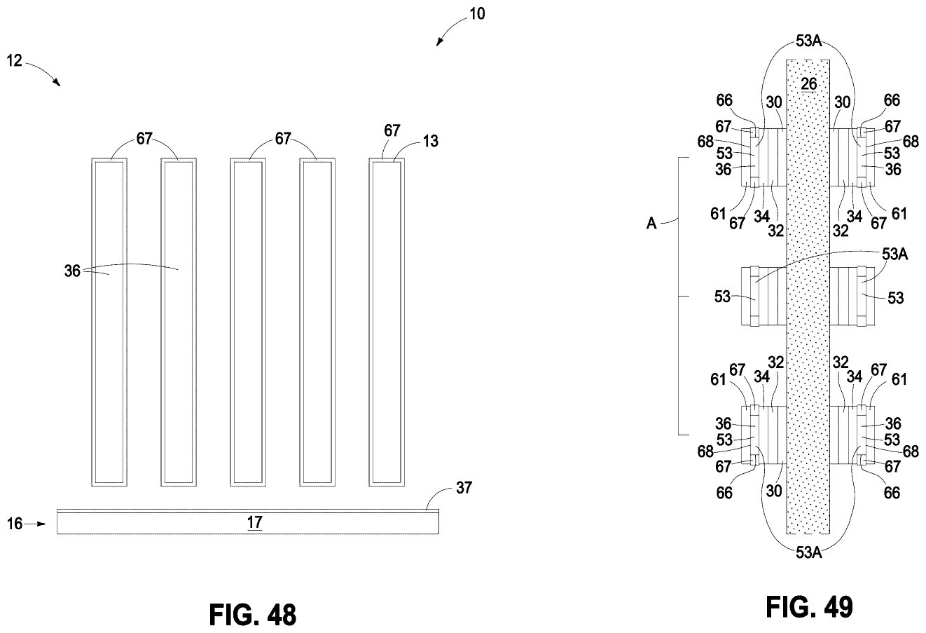

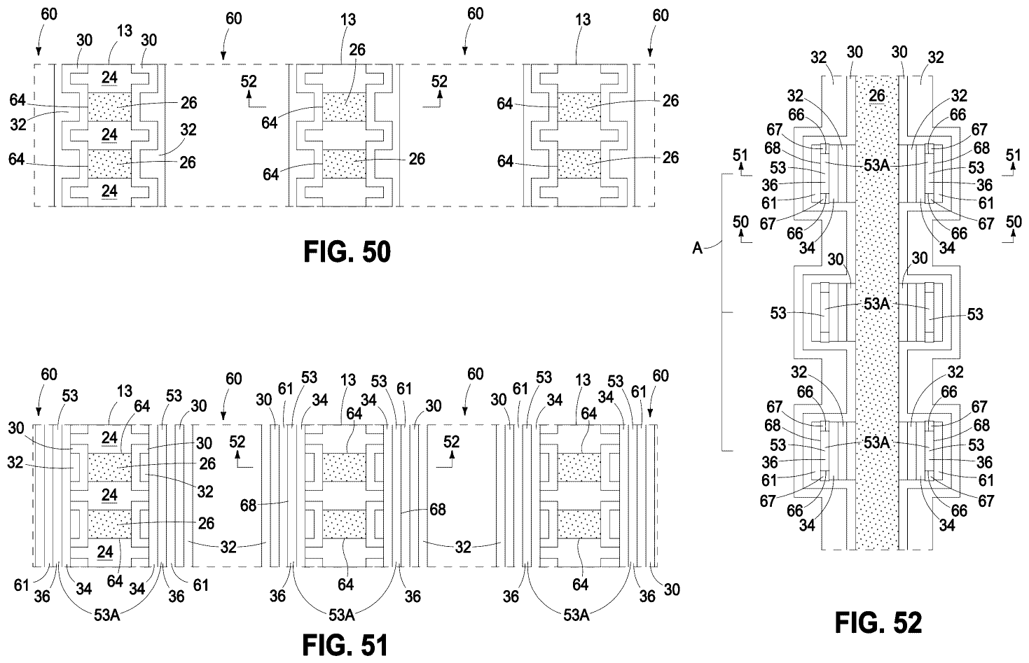

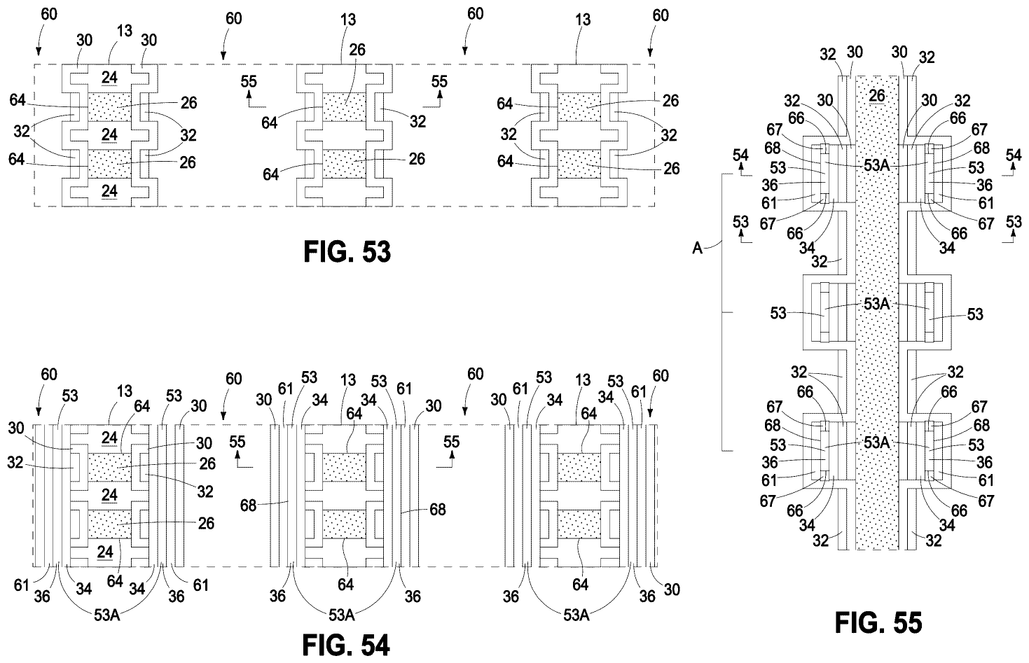

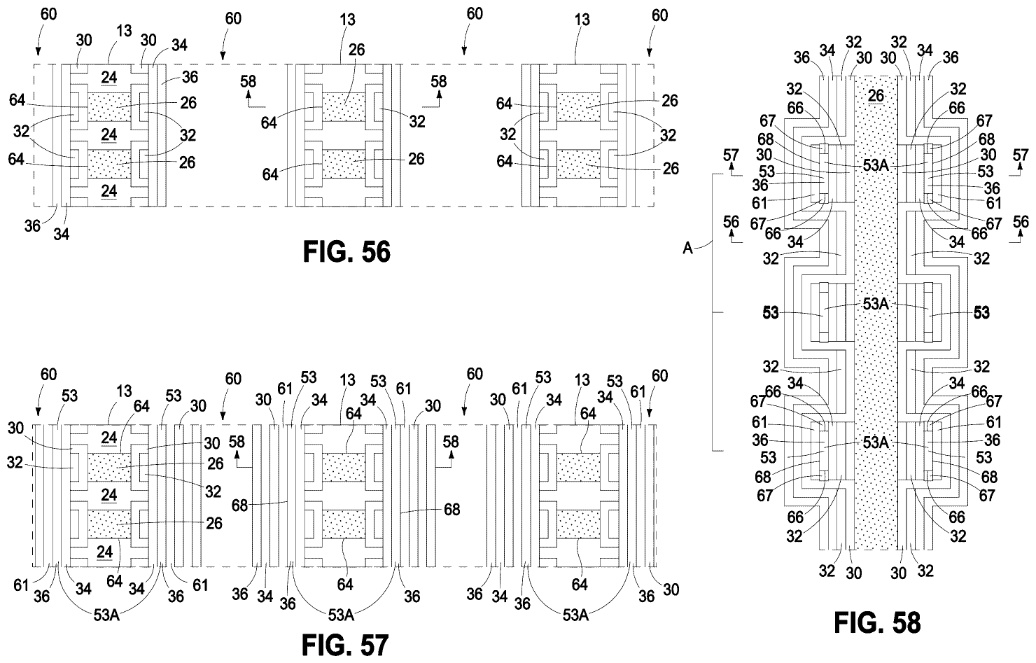

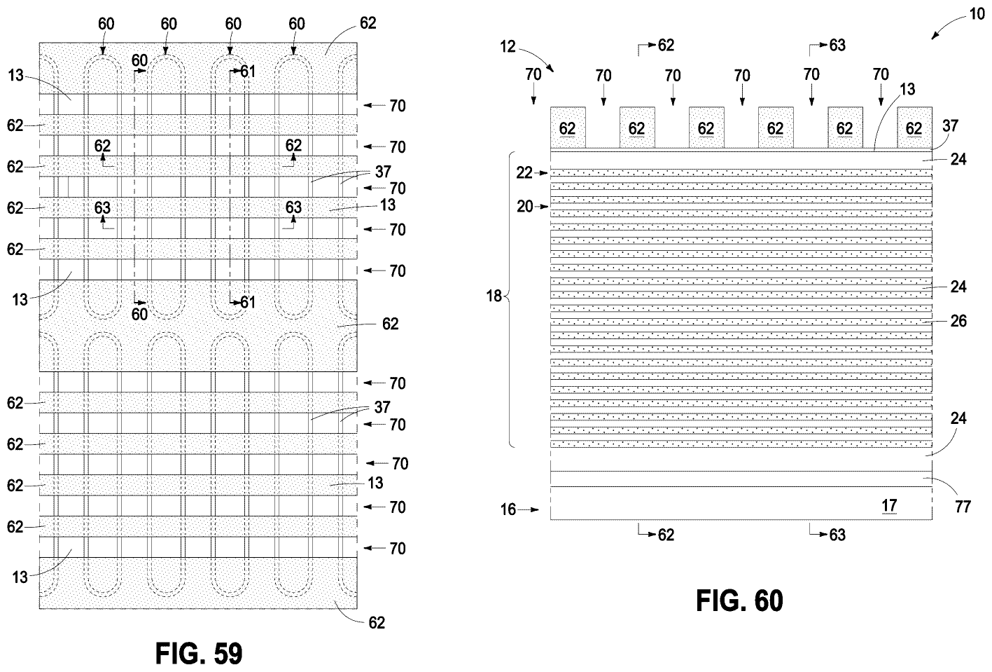

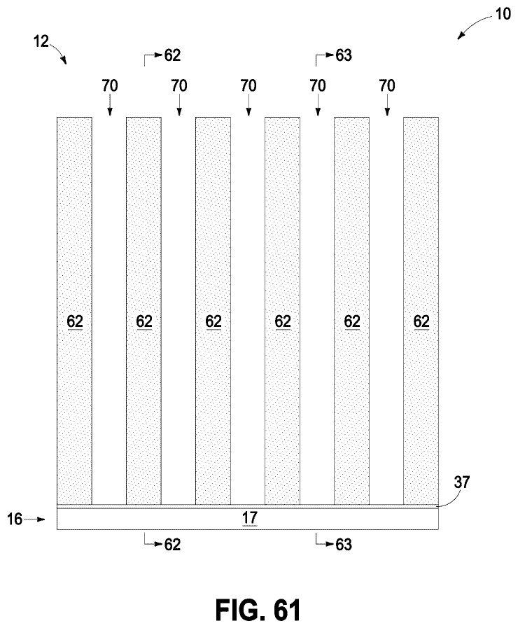

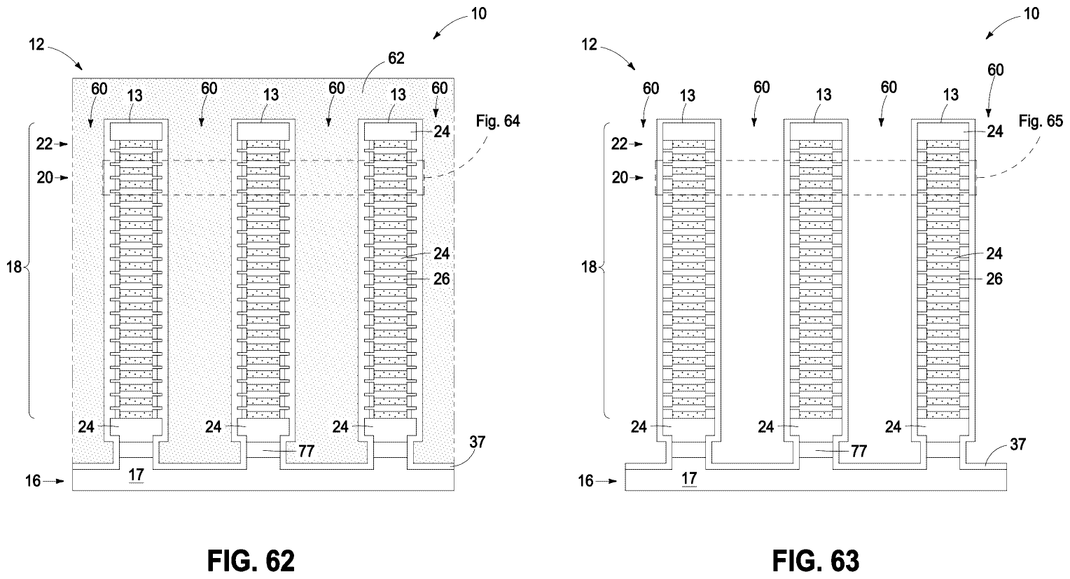

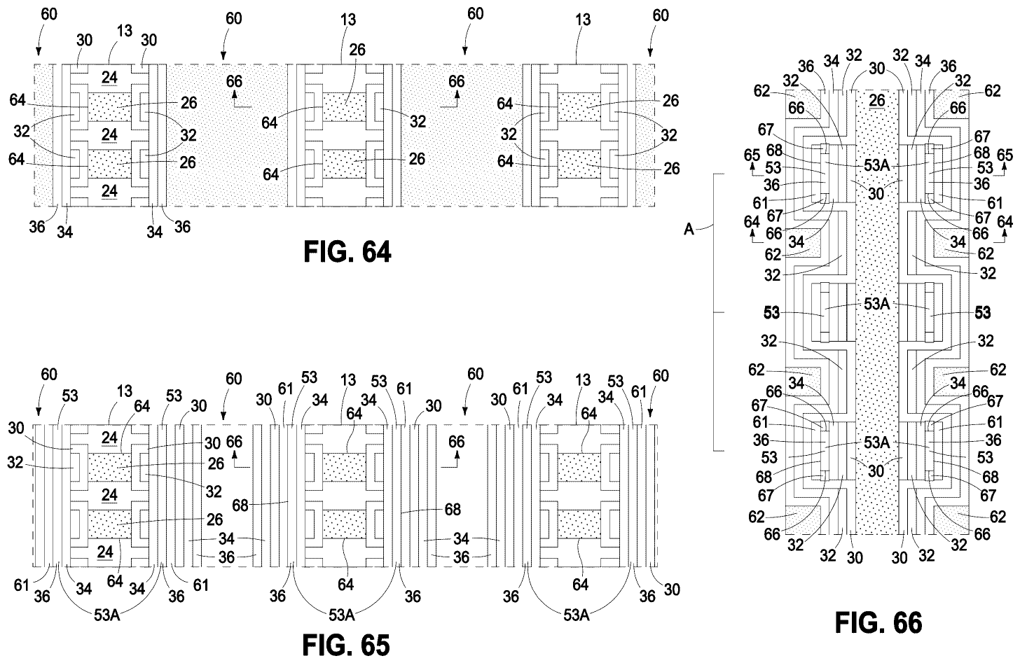

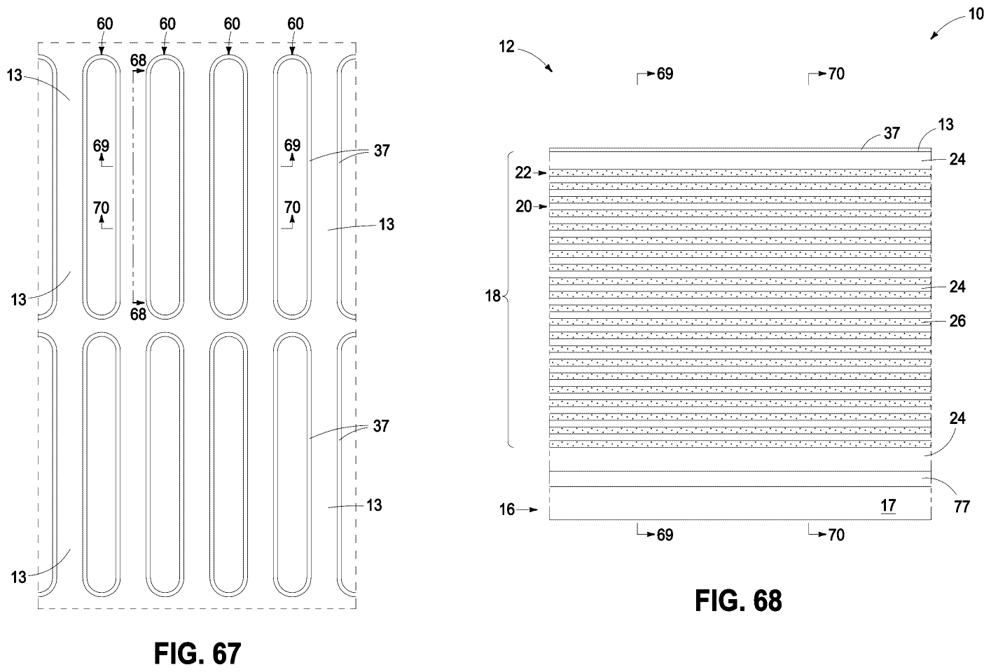

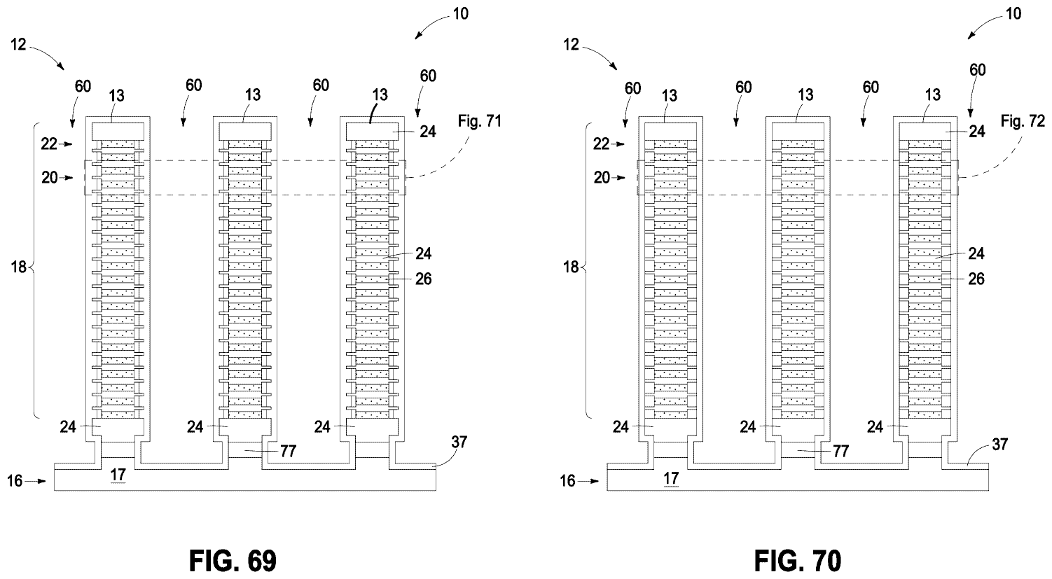

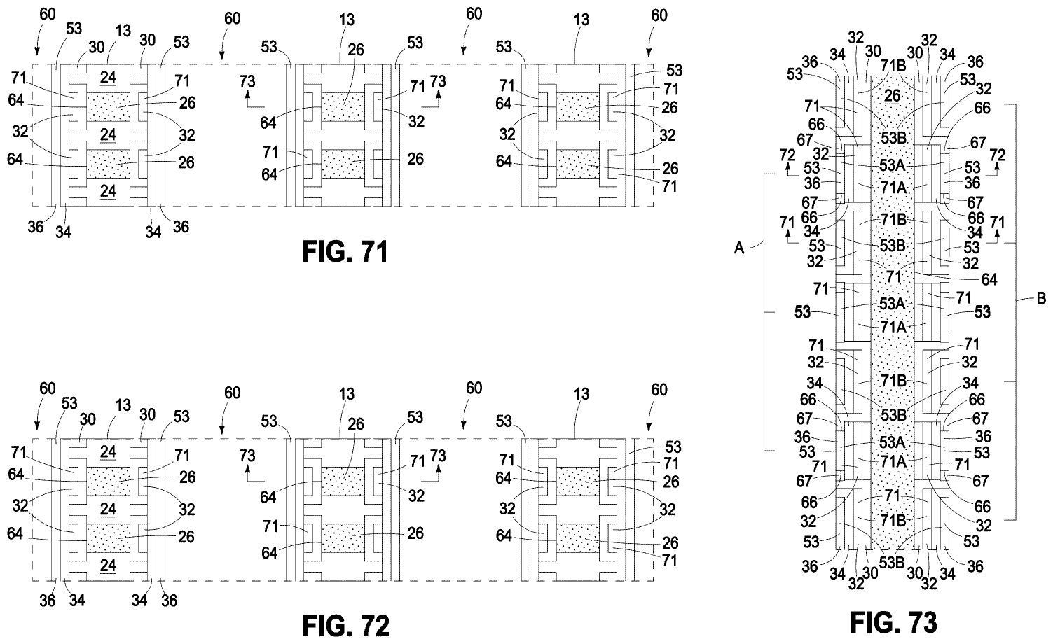

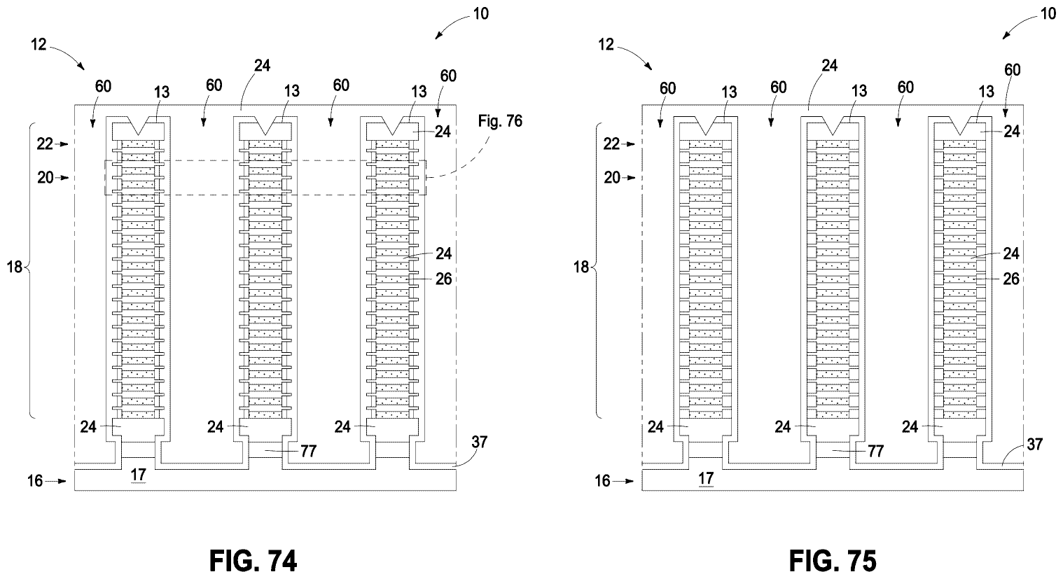

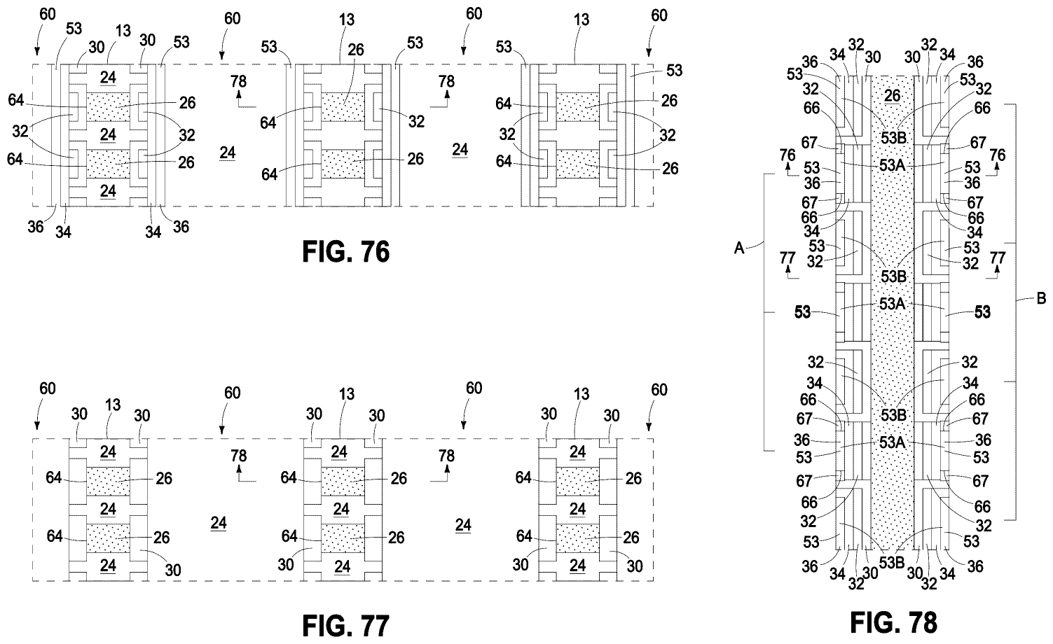

Referring to FIGS. 5 and 6, horizontally-elongated trench openings 60 have been formed through stack 18 to sacrificial etch-stop material 15, leaving patterned sub-stacks 13 there-between. FIG. 7 shows removal of sacrificial etch-stop material 15 (such thereby no longer being shown).

Referring to FIGS. 8-10, sacrificial material 26 has been transversely recessed relative to opposing sidewalls of sub-stacks 13 (e.g., using phosphoric acid when such material is silicon nitride and insulative material 24 is silicon dioxide). FIGS. 11 and 12 show thinning of insulative material 24 of insulative tiers 20 selectively relative to sacrificial material 26 (e.g., using HF per the above compositions for 24 and 26).

Referring to FIGS. 13 and 14, a blocking insulator 30 (e.g., charge-blocking material) has been formed on opposite sides of sub-stacks 13, followed by forming of storage material 32 (e.g., charge-storage material). Example blocking insulators include one or more of silicon hafnium oxide and silicon dioxide. Storage material 32 may be floating-gate material, such as doped or undoped silicon or charge-trapping material such as silicon nitride, metal dots, quantum dots, or nano dots.

Referring to FIGS. 15 and 16, storage material 32 has been transversely etched back relative to sidewalls of sub-stacks 13, followed by removing blocking insulator 30 from such sidewalls, and possible slight transverse thinning of insulative material 24 to ideally make sub-stacks 13 to again have planar opposing sidewalls as shown. FIGS. 17-20 show deposition of a tunnel insulator 34 (e.g., charge-passage material; e.g., a band gap-engineered structure having nitrogen-containing material [e.g., silicon nitride] sandwiched between two insulator oxides [e.g., silicon dioxide]), channel material 36 (e.g., undoped or appropriately-doped crystalline semiconductor material, such as one or more of silicon, germanium, and so-called III/V semiconductor materials [e.g., GaAs, InP, GaP, and GaN]), and an oxidation-restricting material 61 (e.g., silicon nitride). Material 61 may be used to preclude or at least reduce oxidation of transverse sides 68 of channel material 36 (by covering such sides as shown), if such oxidation is conducted, in subsequent processing as will be described below. Materials 30, 32, 34, 36, 61, and other material(s) (including lesser subsets thereof) are collectively shown as and only designated as material 37 in some figures due to scale.

Referring 21-29, sacrificial masking material 62 (e.g., spin-on-carbon) has been deposited to over-fill trench openings 60 and cover sub-stacks 13. Then, sacrificial masking material 62 has been patterned as shown to form trench openings 63 there-through and that are horizontally-elongated orthogonal to the horizontal-elongated direction of trench openings 60 in FIG. 5. FIGS. 30-38 show etching (e.g., wet) of oxidation-restricting material 61, channel material 36, tunnel insulator 34, and storage material 32. FIGS. 39-47 show subsequent etching of blocking insulator 30 (e.g., wet or dry) to expose sacrificial material 26. The artisan is capable of selecting various anisotropic and/or isotropic etching chemistries to achieve the depicted profile depending on compositions of materials 61, 36, 34, 32, and 30. Transverse etching of sacrificial material 26 may be additionally conducted if desired (not shown). Masking material 62 (not shown) has been removed (e.g., by ashing if such is carbon).

The above processing is but one example of forming a first set A of horizontally-spaced pairs 53A of channel-material strings 53 (so spaced by material 26) that extend through first tiers 22 and second tiers 20 of stack 18. In one such embodiment and as shown, construction 10 comprises lines 64 of sacrificial material 26. Such are individually in individual of first tiers 22 and individually extend horizontally through (e.g., through the middle/center of) horizontally-spaced pairs 53A of first set A between channel-material strings 53 in individual of horizontally-spaced pairs of such first set A.

Referring to FIGS. 48 and 49 (positionally corresponding to FIGS. 41 and 47, respectively), and in one embodiment, lateral sidewalls 66 of channel-material strings 53 of first set A have been oxidized. In one such embodiment, channel material 36 of channel-material strings 53 comprises silicon and such oxidizing forms a vertically-continuous mass 67 of silicon dioxide along such lateral sidewalls of channel-material strings 53 of first set A.

Oxidation-restricting material 61, when present being transversely aside channel material 36 before forming of first set A, restricts oxidation of transverse sides 68 of channel material 36 of channel-material strings 53 during such oxidizing. Masses 67 of silicon dioxide when formed may provide better isolation between immediately-laterally-adjacent channel-material strings one of which will be formed in one of the depicted gaps between channel-material-string pairs 53A (not-yet-shown).

Referring to FIGS. 50-52, another layer of blocking insulator 30 and another layer of storage material 32 have been deposited as shown. Such may or may not be of the same respective composition as the first-deposited blocking insulator 30 and storage material 32, but ideally are of the same respective composition. FIGS. 53-55 show exposed storage material 32 as having been transversely etched back (e.g., wet).

Referring to FIGS. 56-58, more tunnel insulator 34 and channel material 36 have been formed. Such may be of the same or different respective composition as the first-deposited tunnel insulator 34 and first-deposited channel material 36, and ideally are of the same respective composition.

Referring to FIGS. 59-66, more sacrificial masking material 62 has been deposited, again to over-fill trench openings 60 and cover sub-stacks 13. Then, sacrificial masking material 62 has been patterned as shown to form trench openings 70 between where trench openings 63 were formed in FIG. 21-29.

Referring to FIGS. 67-73, exposed channel material 36, tunnel insulator 34, blocking insulator 30, and oxidation-barrier material (when present) have been etched back as shown. Alternately, only channel material 36 may be etched back, with tunnel insulator 34, blocking insulator 30, and oxidation-barrier material remaining as such are insulative (not shown). Regardless, such has thereby formed a second set B of horizontally-spaced pairs 53B of channel-material strings 53 that extend through first tiers 22 and second tiers 20, with pairs 53 A in first set A individually horizontally alternating with pairs 53B in second set B. In one such embodiment and as shown, lines 64 of sacrificial material 26 individually extend horizontally through horizontally-spaced pairs 53B of second set B between channel-material strings 53 in individual of horizontally-spaced pairs 53B of second set B.

FIGS. 74-91 show example subsequent/down-stream processing some of which is not particularly material to aspects of the invention. Referring to FIGS. 74-78 (FIGS. 74 and 75 positionally corresponding to FIGS. 69 and 70, respectively), tops of channel material 36 in sets A and B have been patterned and etched to segment such into select gate drain (SGD) sides of channel-material strings 53. Thereafter, the illustrated void-space resulting therefrom and void-space between sub-stacks 13 have been filled with an insulator (e.g., 24) and planarized back as shown. FIGS. 79 and 80 (positionally corresponding to FIGS. 74 and 75, respectively) show formation of more first tiers 22 and more second tiers 20 for ultimate formation of conductive lines for SGD's, followed by formation of example structures 19 having insulative material 24 surrounded by more channel material 36 that is directly against a respective top of channel material 36 of channel-material strings 53.

Referring to FIGS. 81-89, horizontally-elongated trenches 40 have been formed through stack 18, forming memory blocks 58. This has been followed, by way of example only, by replacing of sacrificial material 77 with conductive material 42 after having exposed sidewalls of channel material 36 (not shown) below stack 18 for making sidewall connection therewith and direct electrical coupling with conductor tier 16. Thereafter or before, sacrificial material 26 (no longer shown) has been removed by etching (e.g., with H₃PO₄) and volume resulting from such removing has been filled with conductive material 48 (e.g., conductive metal material). Accordingly, and by way of example only, sacrificial material 26 has been replaced with conductive material 48 to form conductive control-gate lines 29 that individually extend horizontally through horizontally-spaced pairs 53A and 53B between channel-material strings 53 in individual horizontally-spaced pairs 53A and 53B in each of first set A and second set B. In one embodiment, after removing sacrificial materials 26 and prior to the forming conductive material 48, first tiers 22 may be lined with an insulating material (e.g., AlOₓ and not shown), with conductive material 48 being formed thereover (e.g., the replacing of sacrificial material 26 not being entirely with conductive material 48).

The example depicted processing has formed strings 49 of memory cells 56. In one embodiment and as shown, such comprise tunnel insulator 34 and storage material 32, with tunnel insulator 34 in second set B in first tiers 22 extending from between individual of channel-material strings 53 and storage material 32 to be over laterally-opposing sides 69 (FIG. 89) of individual channel-material strings 53. In one such embodiment and as shown, tunnel insulator 34 does not so-extend in first set A. In one such embodiment, tunnel insulator 34 extends through first tiers 22 and second tiers 20. Regardless, in one embodiment, strings 49 of memory cells 56 comprise blocking insulator 30, with such blocking insulator not extending through second tiers 20 (such being vertically isolated/separated from extending-through as shown in FIGS. 86 and 87).

Approximate locations of transistors and/or memory cells 56 are indicated with a bracket in FIG. 89 and some with dashed outlines in FIGS. 86-88. Conductive material 48 may be considered as having control-gate regions 52 (FIG. 89) of individual transistors and/or memory cells 56. Control-gate regions 52 in the depicted embodiment comprise individual portions of individual conductive lines 29.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally outer portion of the storage material (e.g., material 32) where such storage material is insulative (e.g., in the absence of any different-composition material between an insulative storage material 32 and conductive material 48). Regardless, as an additional example, an interface of a storage material and conductive material of a control gate may be sufficient to function as a charge-blocking region in the absence of any separate-composition-insulator material 30. Further, an interface of conductive material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

FIGS. 90 and 91 (positionally corresponding to FIGS. 84 and 85, respectively) show example downstream processing wherein trenches 95 (only one being shown) have been formed to form SGD sub-blocks 96, followed by forming of more insulative material 24 and conductive vias 97 that individually directly electrically couple to individual channel-material strings 53 through channel material 36 of structures 19. Digitlines (not shown) may be subsequently formed that directly electrically couple to multiple of conductive vias 97.

Any other attribute(s) or aspect(s) as shown and/or described herein with respect to other embodiments may be used with respect to the above embodiments.

In one embodiment, a method used in forming memory circuitry comprising memory cells (e.g., 56) that individually comprise storage material (e.g., 32) comprises forming a stack (e.g., 18) comprising vertically-alternating first tiers (e.g., 22) and second tiers (e.g., 20). The first tiers are conductive and the second tiers are insulative at least in a finished-circuitry construction. A first set (e.g., A) of horizontally-spaced pairs (e.g., 71A) of masses (e.g., 71) of the storage material is formed. After forming the first set, a second set (e.g., B) of horizontally-spaced pairs (e.g., 71B) of masses (e.g., 71) of the storage material is formed. The pairs in the first set individually horizontally alternate with the pairs in the second set.

In one embodiment, the memory cells comprise blocking insulator (e.g., 30), part of a control-gate line (e.g., 29), and part of a channel-material string (e.g., 53). The blocking insulator in the first tiers extends from between the part of the control-gate line and the storage material to be over opposing lateral sides (e.g., 72) of each of storage-material masses, the tunnel insulator, and the part of the channel-material string on both transverse sides (e.g., 73) of the part of the control-gate line (FIG. 89).

In one embodiment, the storage-material masses of the first and second sets are individually isolated horizontally and vertically from immediately-adjacent of the storage-material masses by insulative material (e.g., 24, 30). In one such embodiment, the memory cells comprise blocking insulator (e.g., 30), with the insulative material in the horizontal isolation being the blocking insulator.

Any other attribute(s) or aspect(s) as shown and/or described herein with respect to other embodiments may be used.

In one embodiment, a method used in forming memory circuitry comprising memory cells (e.g., 56) that individually comprise storage material (e.g., 32) comprises forming a stack (e.g., 18) comprising vertically-alternating first tiers (e.g., 22) and second tiers (e.g., 20.) The first tiers are conductive and the second tiers are insulative at least in a finished-circuitry construction. A first set (e.g., A in FIGS. 47 and 88) of horizontally-spaced pairs (e.g., 71A) of masses (e.g., 71) of the storage material (e.g., 32) is formed (FIGS. 46 and 47). Lines (e.g., 64) of sacrificial material (e.g., 26) are in individual of the first tiers and individually extend horizontally through the horizontally-spaced pairs of the first set between the storage-material masses in individual of the horizontally-spaced pairs of the first set. After forming the first set, a second set (e.g., B in FIGS. 73 and 88) of horizontally-spaced pairs (e.g., 71B) of masses (e.g., 71) of storage material (e.g., 32) is formed. The pairs in the first set individually horizontally alternate with the pairs in the second set. The lines of sacrificial material individually extend horizontally through the horizontally-spaced pairs of the second set between the storage-material masses in individual of the horizontally-spaced pairs of the second set. After forming the first and second sets, the sacrificial material is replaced with conductive material (e.g., 48) to form conductive control-gate lines (e.g., 29) that individually extend horizontally through the horizontally-spaced pairs between the storage-material masses in the individual horizontally-spaced pairs in each of the first and second sets.

Any other attribute(s) or aspect(s) as shown and/or described herein with respect to other embodiments may be used.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, a memory array comprising strings (e.g., 49) of memory cells (e.g., 56) comprises a stack (e.g., 18) comprising vertically-alternating insulative tiers (e.g., 20) and conductive tiers (e.g., 22). Horizontally-spaced pairs (e.g., 53*, an * being used as a suffix to be inclusive of all such same-numerically-designated structures or portions thereof that may or may not have other suffixes) of channel-material strings (e.g., 53) extend through the insulative tiers and the conductive tiers. Control-gate lines (e.g., 29) are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator (e.g., 34) in the one conductive tier that is adjacent the part of the one channel-material string in the one pair in the one conductive tier, blocking insulator (e.g., 30) in the one conductive tier that is adjacent the part of the one control-gate line in the one pair in the one conductive tier, and storage material (e.g., 32) in the one conductive tier that is between the tunnel insulator and the blocking insulator. The tunnel insulator in the one conductive tier extends from between the part of the one channel-material string in the one pair and the storage material to be over opposing lateral sides (e.g., 69) of the one channel-material string in the one pair.

In one embodiment, the horizontally-spaced pairs of channel-material strings are in first (e.g., A) and second (e.g., B) sets wherein the pairs in the first set individually horizontally alternate with the pairs in the second set. Only one of the first and second sets have the tunnel insulator extending to be over the opposing lateral sides of the one channel-material string. In one such embodiment, in the other of the first and second sets, the one channel-material string in the one pair in the one conductive tier and the storage material in the one conductive tier have opposing coplanar lateral sides (e.g., as would occur if vertically-continuous masses 67 were not present, and not shown). In one embodiment, in the one of the first and second sets, the one channel-material string in the one pair in the one conductive tier and the storage material in the one conductive tier do not have coplanar lateral sides.

In one embodiment, the tunnel insulator extends through the insulative tiers and the conductive tiers, in one embodiment the blocking insulator does not extend through the insulative tiers, and in one embodiment the storage material does not extend through the insulative tiers. In one embodiment, the storage material in immediately adjacent of the memory cells horizontally along opposing transverse sides of the one control-gate line are horizontally separated from one another by insulative material (e.g., 30) that is of different composition from that of the storage material.

Any other attribute(s) or aspect(s) as shown and/or described herein with respect to other embodiments may be used.

In one embodiment, a memory array comprising strings (e.g., 49) of memory cells (e.g., 56) comprises a stack (e.g., 18) comprising vertically-alternating insulative tiers (e.g., 20) and conductive tiers (e.g., 22). Horizontally-spaced pairs (e.g., 53*) of channel-material strings (e.g., 53) extend through the insulative tiers and the conductive tiers. Control-gate lines (e.g., 29) are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator (e.g., 34) in the one conductive tier that is adjacent the part of the one channel-material string in the one pair in the one conductive tier, blocking insulator (e.g., 30) in the one conductive tier that is adjacent the part of the one control-gate line in the one pair in the one conductive tier, and storage material (e.g., 32) in the one conductive tier that is between the tunnel insulator and the blocking insulator. The storage material in immediately adjacent of the memory cells horizontally along opposing transverse sides of the one control-gate line are horizontally separated from one another by insulative material (e.g., 30) that is of different composition from that of the storage material.

In one embodiment, the blocking insulator is directly above and directly below the storage material. In one embodiment, the one channel-material string in the one pair in the one conductive tier and the storage material in the one conductive tier have opposing coplanar lateral sides (e.g., as would occur if vertically-continuous masses 67 were not present, and not shown). In one embodiment, the one channel-material string in the one pair in the one conductive tier and the storage material in the one conductive tier do not have coplanar lateral sides.

Any other attribute(s) or aspect(s) as shown and/or described herein with respect to other embodiments may be used.

In one embodiment, a memory array comprising strings (e.g., 49) of memory cells (e.g., 56) comprises a stack (e.g., 18) comprising vertically-alternating insulative tiers (e.g., 20) and conductive tiers (e.g., 22). Horizontally-spaced pairs (e.g., 53*) of channel-material strings (e.g., 53) extend through the insulative tiers and the conductive tiers. Control-gate lines (e.g., 29) are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator (e.g., 34) in the one conductive tier that is adjacent the part of the one channel-material string in the one pair in the one conductive tier, blocking insulator (e.g., 30) in the one conductive tier that is adjacent the part of the one control-gate line in the one pair in the one conductive tier, and storage material (e.g., 32) in the one conductive tier that is between the tunnel insulator and the blocking insulator. The tunnel insulator in immediately-adjacent of the memory cells horizontally along opposing transverse sides (e.g., 73) of the one control-gate line are horizontally separated from one another by insulative material (e.g., 30) that is of different composition from that of the tunnel insulator.

In one embodiment, the insulative material comprises a transverse extension of the blocking insulator that is between the part of the one control-gate line in the one pair and the storage material. In one embodiment, the tunnel insulator extends through the insulative tiers and the conductive tiers.

Any other attribute(s) or aspect(s) as shown and/or described herein with respect to other embodiments may be used.

In one embodiment, a memory array comprising strings (e.g., 49) of memory cells (e.g., 56) comprises a stack (e.g., 18) comprising vertically-alternating insulative tiers (e.g., 20) and conductive tiers (e.g., 22). Horizontally-spaced pairs (e.g., 53*) of channel-material strings (e.g., 53) extend through the insulative tiers and the conductive tiers. Control-gate lines (e.g., 29) are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator (e.g., 34) in the one conductive tier that is adjacent the part of the one channel-material string in the one pair in the one conductive tier, blocking insulator (e.g., 30) in the one conductive tier that is adjacent the part of the one control-gate line in the one pair in the one conductive tier, and storage material (e.g., 32) in the one conductive tier that is between the tunnel insulator and the blocking insulator. The blocking insulator in the one conductive tier extends from between the part of the one control-gate line in the one pair and the storage material to be over opposing lateral sides of each of the storage material, the tunnel insulator, and the one channel-material string in the one pair on both transverse sides of the one control-gate line.

In one embodiment, each of the respective opposing lateral sides of the storage material and the tunnel insulator are coplanar. In one embodiment, the blocking insulator is directly above and directly below the storage material.

Any other attribute(s) or aspect(s) as shown and/or described herein with respect to other embodiments may be used.

In some prior methods and constructions, small circular openings in which channel-material strings will be received are etched completely through the stack. Further, gates of memory cells comprising such channel-material strings typically completely circumferentially surround such channel-material strings (gate-all-around). In some embodiments of the invention compared to such prior methods, etching through the stack to form openings in which channel-material strings are received may be easier. In some embodiments of the invention compared to such prior constructions, greater memory cell density may be achieved in the absence of gate-all-around. In some embodiments of the invention compared to such prior constructions, better lateral memory cell isolation between immediately-laterally-adjacent memory cells and better memory cell performance may be achieved due to better storage material separation between immediately-laterally-adjacent memory cells.

The memory circuitry described herein (e.g., conductive vias thereof) may connect with circuitry that is on either the top or the bottom (i.e., either z-axis side) of the stack regardless of orientation of the construction in three-dimensional space and which is not material to aspects of the inventions disclosed herein. For example, and by way of example only, the conductive vias may connect with peripheral control circuitry that is beneath the stack with respect to the orientation shown in the drawings. As an alternate example, and by way of example only, the conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, source lines or plates may be fabricated relative to the bottom of the stack with respect to the shown orientation but inverted therefrom during processing. Such source lines or plates may connect with conductive vias that extend through the stack to the substrate bonded with the other side that has such peripheral control circuitry. Regardless, constructions as shown and described herein may be processed, packaged, and/or mounted in any three-dimensional spatial orientation.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modules, modems, processor and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication and as shown in drawings (if any) herein, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space during fabrication and/or in a finished construction. Additionally, “elevationally-extending”and “extend (ing) elevationally” refer to a direction that is angled away by at least 45° from exactly horizontal. Further, “extend (ing) elevationally”, “elevationally-extending”, “extend (ing) horizontally”, “horizontally-extending” and the like with respect to a field effect transistor are with reference to orientation of the transistor's channel length along which current flows in operation between the source/drain regions. For bipolar junction transistors, “extend (ing) elevationally” “elevationally-extending”, “extend (ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprising strings of memory cells comprising channel-material strings comprises forming a stack comprising vertically-alternating first tiers and second tiers. The first tiers are conductive and the second tiers are insulative at least in a finished-circuitry construction. A first set of horizontally-spaced pairs of channel-material strings are formed to extend through the first tiers and the second tiers. After forming the first set, a second set of horizontally-spaced pairs of channel-material strings is formed to extend through the first tiers and the second tiers. The pairs in the first set individually horizontally alternate with the pairs in the second set.

In some embodiments, a method used in forming memory circuitry comprising memory cells that individually comprise storage material comprises forming a stack comprising vertically-alternating first tiers and second tiers. The first tiers are conductive and the second tiers are insulative at least in a finished-circuitry construction. A first set of horizontally-spaced pairs of masses of the storage material is formed. After forming the first set, a second set of horizontally-spaced pairs of masses of the storage material is formed. The pairs in the first set individually horizontally alternate with the pairs in the second set.

In some embodiments, a method used in forming memory circuitry comprising strings of memory cells comprising channel-material strings comprises forming a stack comprising vertically-alternating first tiers and second tiers. The first tiers are conductive and the second tiers are insulative at least in a finished-circuitry construction. A first set of horizontally-spaced pairs of channel-material strings is formed to extend through the first tiers and the second tiers. Lines of sacrificial material are in individual of the first tiers and individually extend horizontally through the horizontally-spaced pairs of the first set between the channel-material strings in individual of the horizontally-spaced pairs of the first set. After forming the first set, a second set of horizontally-spaced pairs of channel-material strings is formed to extend through the first tiers and the second tiers. The pairs in the first set individually horizontally alternate with the pairs in the second set. The lines of sacrificial material individually extend horizontally through the horizontally-spaced pairs of the second set between the channel-material strings in individual of the horizontally-spaced pairs of the second set. After forming the first and second sets, the sacrificial material is replaced with conductive material to form conductive control-gate lines that individually extend horizontally through the horizontally-spaced pairs between the channel-material strings in the individual horizontally-spaced pairs in each of the first and second sets.

In some embodiments, a method used in forming memory circuitry comprising memory cells that individually comprise storage material comprises forming a stack comprising vertically-alternating first tiers and second tiers. The first tiers are conductive and the second tiers are insulative at least in a finished-circuitry construction. A first set of horizontally-spaced pairs of masses of the storage material is formed. Lines of sacrificial material are in individual of the first tiers and individually extend horizontally through the horizontally-spaced pairs of the first set between the storage-material masses in individual of the horizontally-spaced pairs of the first set. After forming the first set, a second set of horizontally-spaced pairs of masses of the storage material is formed. The pairs in the first set individually horizontally alternate with the pairs in the second set. The lines of sacrificial material individually extend horizontally through the horizontally-spaced pairs of the second set between the storage-material masses in individual of the horizontally-spaced pairs of the second set. After forming the first and second sets, the sacrificial material is replaced with conductive material to form conductive control-gate lines that individually extend horizontally through the horizontally-spaced pairs between the storage-material masses in the individual horizontally-spaced pairs in each of the first and second sets.

In some embodiments, a memory array comprising strings of memory cells comprises a stack comprising vertically-alternating insulative tiers and conductive tiers. Horizontally-spaced pairs of channel-material strings extend through the insulative tiers and the conductive tiers. Control-gate lines are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator in the one conductive tier that is adjacent the part of the one channel-material string in the one pair in the one conductive tier, blocking insulator in the one conductive tier that is adjacent the part of the one control-gate line in the one pair in the one conductive tier, and storage material in the one conductive tier that is between the tunnel insulator and the blocking insulator. The tunnel insulator in the one conductive tier extends from between the part of the one channel-material string in the one pair and the storage material to be over opposing lateral sides of the one channel-material string in the one pair.

In some embodiments, a memory array comprising strings of memory cells comprises a stack comprising vertically-alternating insulative tiers and conductive tiers. Horizontally-spaced pairs of channel-material strings extend through the insulative tiers and the conductive tiers. Control-gate lines are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator in the one conductive tier that is adjacent the part of the one channel-material string in the one pair in the one conductive tier, blocking insulator in the one conductive tier that is adjacent the part of the one control-gate line in the one pair in the one conductive tier, and storage material in the one conductive tier that is between the tunnel insulator and the blocking insulator. The storage material in immediately adjacent of the memory cells horizontally along opposing transverse sides of the one control-gate line are horizontally separated from one another by insulative material that is of different composition from that of the storage material.

In some embodiments, a memory array comprising strings of memory cells comprises a stack comprising vertically-alternating insulative tiers and conductive tiers. Horizontally-spaced pairs of channel-material strings extend through the insulative tiers and the conductive tiers. Control-gate lines are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator in the one conductive tier that is adjacent the part of the one channel-material string in the one pair in the one conductive tier, blocking insulator in the one conductive tier that is adjacent the part of the one control-gate line in the one pair in the one conductive tier, and storage material in the one conductive tier that is between the tunnel insulator and the blocking insulator. The tunnel insulator in immediately-adjacent of the memory cells horizontally along opposing transverse sides of the one control-gate line are horizontally separated from one another by insulative material that is of different composition from that of the tunnel insulator.

In some embodiments, a memory array comprising strings of memory cells comprises a stack comprising vertically-alternating insulative tiers and conductive tiers. Horizontally-spaced pairs of channel-material strings extend through the insulative tiers and the conductive tiers. Control-gate lines are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator in the one conductive tier that is adjacent the part of the one channel-material string in the one pair in the one conductive tier, blocking insulator in the one conductive tier that is adjacent the part of the one control-gate line in the one pair in the one conductive tier, and storage material in the one conductive tier that is between the tunnel insulator and the blocking insulator. The blocking insulator in the one conductive tier extends from between the part of the one control-gate line in the one pair and the storage material to be over opposing lateral sides of each of the storage material, the tunnel insulator, and the one channel-material string in the one pair on both transverse sides of the one control-gate line.

In some embodiments, a memory array comprising strings of memory cells comprises a stack comprising vertically-alternating insulative tiers and conductive tiers. Horizontally-spaced pairs of channel-material strings extend through the insulative tiers and the conductive tiers. Control-gate lines are in individual of the conductive tiers and individually extend horizontally through the horizontally-spaced pairs between the channel-material strings in individual of the horizontally-spaced pairs. The memory cells individually comprise part of one of the channel-material strings in one of the pairs in one of the conductive tiers, part of one of the control-gate lines in the one pair in the one conductive tier, tunnel insulator in the one conductive tier that is adjacent the part of the one channel-material string in the one pair in the one conductive tier, blocking insulator in the one conductive tier that is adjacent the part of the one control-gate line in the one pair in the one conductive tier, and storage material in the one conductive tier that is between the tunnel insulator and the blocking insulator. The tunnel insulator in the one conductive tier extends from between the part of the one channel-material string in the one pair and the storage material to be over opposing lateral sides of the one channel-material string in the one pair. The storage material in immediately adjacent of the memory cells horizontally along opposing transverse sides of the one control-gate line are horizontally separated from one another by insulative material that is of different composition from that of the storage material. The tunnel insulator in immediately-adjacent of the memory cells horizontally along the opposing transverse sides of the one control-gate line are horizontally separated from one another by insulative material that is of different composition from that of the tunnel insulator. The blocking insulator in the one conductive tier extends from between the part of the one control-gate line in the one pair and the storage material to be over opposing lateral sides of each of the storage material, the tunnel insulator, and the one channel-material string in the one pair on both transverse sides of the one control-gate line.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising strings of memory cells comprising channel-material strings, comprising:
forming a stack comprising vertically-alternating first tiers and second tiers, the first tiers being conductive and the second tiers being insulative at least in a finished-circuitry construction;
forming a first set of horizontally-spaced pairs of channel-material strings extending through the first tiers and the second tiers; and
after forming the first set, forming a second set of horizontally-spaced pairs of channel-material strings extending through the first tiers and the second tiers, the pairs in the first set individually horizontally alternating with the pairs in the second set.

2. The method of claim 1 comprising oxidizing lateral sidewalls of the channel-material strings of the first set before forming the second set.

3. The method of claim 2 wherein channel material of the channel-material strings comprises silicon and the oxidizing forms a vertically-continuous mass of silicon dioxide along the lateral sidewalls of the channel-material strings of the first set before forming the second set.

4. The method of claim 2 wherein the channel-material strings comprise channel material, and further comprising:
forming an oxidation barrier material transversally aside the channel material before forming the first set, the oxidation barrier material restricting oxidation of transverse sides of the channel material of the channel-material strings during the oxidizing.

5. The method of claim 4 wherein the channel material comprises silicon and the oxidizing forms a vertically-continuous mass of silicon dioxide along the lateral sidewalls of the channel-material strings of the first set before forming the second set.

6. The method of claim 1 wherein the strings of memory cells comprise tunnel insulator and storage material, the tunnel insulator in the second set in the first tiers extending from between individual of the channel-material strings and the storage material to be over opposing lateral sides of the individual channel-material strings.

7. The method of claim 6 wherein the tunnel insulator does not so-extend in the first set.

8. The method of claim 6 wherein the tunnel insulator extends through the first tiers and the second tiers.

9. The method of claim 1 wherein the strings of memory cells comprise blocking insulator, the blocking insulator not extending through the second tiers.

10. A method used in forming memory circuitry comprising memory cells that individually comprise storage material, comprising:
forming a stack comprising vertically-alternating first tiers and second tiers, the first tiers being conductive and the second tiers being insulative at least in a finished-circuitry construction;
forming a first set of horizontally-spaced pairs of masses of the storage material; and
after forming the first set, forming a second set of horizontally-spaced pairs of masses of the storage material, the pairs in the first set individually horizontally alternating with the pairs in the second set.

11. The method of claim 10 wherein the memory cells comprise blocking insulator, part of a control-gate line, and part of a channel-material string; the blocking insulator in the first tiers extending from between the part of the control-gate line and the storage material to be over opposing lateral sides of each of the storage-material masses, the tunnel insulator, and the part of the channel-material string on both transverse sides of the part of the control-gate line.

12. The method of claim 10 wherein the storage-material masses of the first and second sets are individually isolated horizontally and vertically from immediately-adjacent of the storage-material masses by insulative material.

13. The method of claim 12 wherein the memory cells comprise blocking insulator, the insulative material in the horizontal isolation being the blocking insulator.

14. A method used in forming memory circuitry comprising strings of memory cells comprising channel-material strings, comprising:
forming a stack comprising vertically-alternating first tiers and second tiers, the first tiers being conductive and the second tiers being insulative at least in a finished-circuitry construction;
forming a first set of horizontally-spaced pairs of channel-material strings extending through the first tiers and the second tiers, lines of sacrificial material being in individual of the first tiers and that individually extend horizontally through the horizontally-spaced pairs of the first set between the channel-material strings in individual of the horizontally-spaced pairs of the first set;
after forming the first set, forming a second set of horizontally-spaced pairs of channel-material strings extending through the first tiers and the second tiers, the pairs in the first set individually horizontally alternating with the pairs in the second set, the lines of sacrificial material individually extending horizontally through the horizontally-spaced pairs of the second set between the channel-material strings in individual of the horizontally-spaced pairs of the second set; and
after forming the first and second sets, replacing the sacrificial material with conductive material to form conductive control-gate lines that individually extend horizontally through the horizontally-spaced pairs between the channel-material strings in the individual horizontally-spaced pairs in each of the first and second sets.

15. The method of claim 14 comprising oxidizing lateral sidewalls of the channel-material strings of the first set before forming the second set.

16. The method of claim 14 wherein the strings of memory cells comprise tunnel insulator and storage material, the tunnel insulator in the second set in the first tiers extending from between individual of the channel-material strings and the storage material to be over opposing lateral sides of the individual channel-material strings.

17. A method used in forming memory circuitry comprising memory cells that individually comprise storage material, comprising:
forming a stack comprising vertically-alternating first tiers and second tiers, the first tiers being conductive and the second tiers being insulative at least in a finished-circuitry construction;
forming a first set of horizontally-spaced pairs of masses of the storage material, lines of sacrificial material being in individual of the first tiers and that individually extend horizontally through the horizontally-spaced pairs of the first set between the storage-material masses in individual of the horizontally-spaced pairs of the first set;
after forming the first set, forming a second set of horizontally-spaced pairs of masses of the storage material, the pairs in the first set individually horizontally alternating with the pairs in the second set, the lines of sacrificial material individually extending horizontally through the horizontally-spaced pairs of the second set between the storage-material masses in individual of the horizontally-spaced pairs of the second set; and
after forming the first and second sets, replacing the sacrificial material with conductive material to form conductive control-gate lines that individually extend horizontally through the horizontally-spaced pairs between the storage-material masses in the individual horizontally-spaced pairs in each of the first and second sets.

18. The method of claim 17 wherein the memory cells comprise blocking insulator, part of a control-gate line, and part of a channel-material string; the blocking insulator in the first tiers extending from between the part of the control-gate line and the storage material to be over opposing lateral sides of each of the storage-material masses, the tunnel insulator, and the part of the channel-material string on both transverse sides of the part of the control-gate line.

19. The method of claim 17 wherein the storage-material masses are individually isolated horizontally and vertically from immediately-adjacent of the storage-material masses by insulative material.
